(19) United States
(12) Patent Application Publication
(10) Pub. No.: US 2026/0123227 A1
(43) Pub. Date: Apr. 30, 2026

(54) LIGHT EMITTING DISPLAY DEVICE

(71) Applicant: SAMSUNG DISPLAY CO., LTD., Yongin-si (KR)

(72) Inventors: Chan Young KIM, Yongin-si (KR); Seong-Yong HWANG, Yongin-si (KR); Sang Woo KANG, Yongin-si (KR); Choong Youl IM, Yongin-si (KR); Seong Min CHO, Yongin-si (KR); Beohm Rock CHOI, Yongin-si (KR)

(21) Appl. No.: 19/037,565

(22) Filed: Jan. 27, 2025

(30) Foreign Application Priority Data
May 29, 2024 (KR) 10-2024-0070313

(51) Int. Cl. H10K 59/38; H10K 59/122; H10K 59/126

(52) U.S. Cl. CPC H10K 59/38; H10K 59/122; H10K 59/126

(57) ABSTRACT

A light emitting display device or an electronic device includes a display panel including a display area and a component area surrounded by the display area having photosensor regions and an optical element disposed on a rear surface of the component area, wherein the display area and the component area include a substrate, anodes disposed on the substrate, a pixel defining layer having first openings overlapping the anodes, light emitting layers disposed in the first openings of the pixel defining layer, a cathode formed on the light emitting layers and the pixel defining layer, an encapsulation layer disposed on the cathode, and a light blocking layer disposed on the encapsulation layer and including second openings corresponding to the first openings, wherein an area of the second opening in the display area corresponding to a first color is narrower than an area of the second opening of the component area.

This application claims priority to Korean Patent Application No. 10-2024-0070313, filed on May 29, 2024, and all the benefits accruing therefrom under 35 U.S. C. § 119, the content of which in its entirety is herein incorporated by reference.

### BACKGROUND

### 1. Field

The present invention relates to a light emitting display device and an electronic device including the light emitting display device.

### 2. Description of the Related Art

Display devices display images and include a liquid crystal display (LCD) and an organic light emitting diode (OLED). The display devices are used for electronic devices such as mobile phones, GPS, digital cameras, electronic books, portable gaming devices, and various terminals.

Display devices, such as the organic light emitting device, may be folded or bent by using a flexible substrate.

In addition, in small electronic devices such as portable phones, optical elements such as cameras and optical sensors are formed in a bezel area around the display area, but as the size of the display screen is increased, the size of the peripheral area of the display area gradually decreases.

### SUMMARY

The invention provides a light emitting display device for controlling a color difference and/or a difference in luminance ratios according to lateral viewing angles of images displayed in a normal display area and a component area corresponding to an optical element, such as a sensor, disposed on a rear surface of a display panel.

Embodiments are intended to provide a light emitting display device for removing drawbacks that an internal pattern is visible to a user or that an image is invisible to the user when no polarizer is formed on a front surface of a display panel and external light is reflected.

The invention provides a light emitting display device for forming no polarizer on a front surface of a display panel, forming no black light blocking layer, and for overlapping multiple color filters to prevent reflection and transmission of external light and to reduce time and cost for a manufacturing process.

An embodiment provides a light emitting display device including a display panel including a normal display area and a component area surrounded by the normal display area having photosensor regions and an optical element disposed on a rear surface of the component area, wherein the normal display area and the component area include a substrate, anodes disposed on the substrate, a pixel defining layer having first openings overlapping the anodes, light emitting layers disposed in the first openings of the pixel defining layer, a cathode formed on the light emitting layers and the pixel defining layer, an encapsulation layer disposed on the cathode, and a light blocking layer disposed on the encapsulation layer and including second openings corresponding to the first openings, wherein an area of the second opening in the normal display area corresponding to a first color is formed to be narrower than an area of the second opening of the component area.

In an embodiment, the second opening of the component area may have a narrower width than the second opening of the normal display area by greater than about 0 μm and equal to or less than about 2 μm.

In an embodiment, the light emitting display device may further include color filters disposed on the light blocking layer, wherein the color filter of the color formed last from among the color filters may have a height difference equal to or greater than about −0.3 μm and equal to or less than about 0.2 μm in the component area, compared to the normal display area.

In an embodiment, the pixel defining layer may further include a photosensor region first opening corresponding to the photosensor region.

In an embodiment, the light blocking layer may further include a photosensor region second opening corresponding to the photosensor region and the photosensor region first opening.

In an embodiment, the color filter of one color may be disposed in the photosensor region second opening.

In an embodiment, the photosensor region first opening may be disposed in the pixel defining layer of the normal display area, and the photosensor region first opening of the normal display area may overlap the light blocking layer.

In an embodiment, an area of the second opening of the component area corresponding to a color that is different from the first color may be formed to be narrower than an area of the second opening corresponding to the different color of the normal display area.

In an embodiment, the second opening disposed in the component area corresponding to any color may be formed to have a narrower area than the second opening of the corresponding color of the normal display area.

In an embodiment, a ratio of the narrowed area of the second opening of the component area corresponding to the first color may be equal to a ratio of the narrowed area of the second opening of the component area corresponding to the different color or may be different from the same by about equal to or less than about 5%.

Another embodiment provides a light emitting display device including a display panel including a normal display area and a component area surrounded by the normal display area having photosensor regions and an optical element disposed on a rear surface of the component area, wherein the normal display area and the component area include a substrate, anodes disposed on the substrate, a pixel defining layer having first openings overlapping the anodes, light emitting layers disposed in the first openings of the pixel defining layer, a cathode formed on the light emitting layers and the pixel defining layer, an encapsulation layer disposed on the cathode and color filters corresponding to different colors disposed on the encapsulation layer, wherein at least two of the color filters overlap each other in a light blocking area of the color filter, and wherein the color filters include second openings in which one of the color filters is disposed, and wherein an area of the second opening of the normal display area corresponding to a first color is formed to be narrower than an area of the second opening of the component area.

In an embodiment, the second opening of the component area may have a narrower width than the second opening of the normal display area by greater than about 0 μm and equal to or less than about 2 μm.

In an embodiment, the color filter of the color formed last from among the color filters may have a height difference of equal to or greater than about −0.3 μm and equal to or less than about 0.2 μm in the component area, compared to the normal display area.

In an embodiment, the pixel defining layer may further include a photosensor region first opening corresponding to the photosensor region.

In an embodiment, the light blocking area of the color filter may further include a photosensor region second opening corresponding to the photosensor region and the photosensor region first opening.

In an embodiment, a color filter of one color may be disposed in the photosensor region second opening.

In an embodiment, the photosensor region first opening may be disposed in the pixel defining layer of the normal display area, and the photosensor region first opening of the normal display area may overlap the light blocking area of the color filter.

In an embodiment, an area of the second opening of the component area corresponding to a color that is different from the first color may be formed to be narrower than an area of the second opening corresponding to the different color of the normal display area.

In an embodiment, the second opening disposed in the component area corresponding to any color may be formed to be narrower than an area of the second opening of the corresponding color of the normal display area.

In an embodiment, a ratio of the narrowed area of the second opening of the component area corresponding to the first color may be about equal to a ratio of the narrowed area of the second opening of the component area corresponding to the different color or may differ by no more than about 5%.

According to an embodiment, the area of the second opening of the light blocking layer disposed in the component area may be formed to be different from the area of the second opening of the light blocking layer disposed in the normal display area so that the color difference and/or difference in luminance ratios according to the lateral viewing angle of the images displayed by the two regions may not be generated or may be scarcely generated.

According to an embodiment, the area of the second opening from among the light blocking area of the overlapping color filters disposed in the component area may be formed to be different from the area of the second opening from among the light blocking area of the overlapping color filters disposed in the normal display area so that the color difference and/or difference in luminance ratios according to the lateral viewing angle of the images displayed by the two regions may not be generated or may be scarcely generated.

According to an embodiment, no polarizer or light blocking layer may be formed on the front surface of the display panel, and external light may be prevented from being reflected and transmitted by overlapping the color filters and not the light blocking layer, thereby reducing the time and cost of the manufacturing process.

The drawbacks that the internal pattern is visible to the user or the image is not easily visible to the user when the external light is reflected may be removed by overlapping the color filters, according to an embodiment.

### BRIEF DESCRIPTION OF THE DRAWINGS

FIG. 1 shows a perspective view of a using state of a display device, according to an embodiment.

FIG. 2 shows an exploded perspective view of a display device, according to an embodiment.

FIG. 3 shows a block diagram of a display device, according to an embodiment.

FIG. 4 shows a perspective view of a light emitting display device, according to another embodiment.

FIG. 5 shows a top down plan view of an enlarged region of a light emitting display device, according to an embodiment.

FIG. 6 shows a top down plan view of a portion of a normal display area of a light emitting display device, according to an embodiment.

FIG. 7 shows a cross-sectional view of the portion of a normal display area of a light emitting display device of FIG. 6 with respect to a cross-sectional line VII-VII′, according to an embodiment.

FIG. 8 shows a top plan view of a portion from among a first component area of a light emitting display device, according to an embodiment.

FIG. 9 shows a cross-sectional view with respect to a cross-sectional line IX-IX′ of FIG. 8, according to an embodiment.

FIG. 10 shows a color coordinate map of changes of color impressions of a light emitting display device, according to an embodiment.

FIG. 11 shows a top plan view on a portion from among a normal display area of a light emitting display device, according to another embodiment.

FIG. 12 shows a cross-sectional view with respect to a cross-sectional line XII-XII′ of FIG. 11, according to an embodiment.

FIG. 13 shows a top plan view on a portion from among a first component area of a light emitting display device, according to another embodiment.

FIG. 14 shows a cross-sectional view with respect to a cross-sectional line XIV-XIV′ of FIG. 13, according to an embodiment.

FIG. 15 shows a color coordinate map of a difference of color impressions of a light emitting display device, according to a comparative example.

FIG. 16 shows a top plan view on a portion from among a first component area of a light emitting display device, according to another embodiment.

FIG. 17 shows a cross-sectional view with respect to a cross-sectional line XVII-XVII′ of FIG. 16, according to an embodiment.

FIG. 18 shows a color coordinate map of changes of color impressions of a light emitting display device according to the embodiments of FIG. 16 and FIG. 17.

FIG. 19 shows a structure of respective layers according to order for manufacturing a portion of a pixel circuit from among a lower panel layer of a light emitting display device, according to an embodiment.

FIG. 20 shows a structure of respective layers according to order for manufacturing a portion of a pixel circuit from among a lower panel layer of a light emitting display device, according to an embodiment.

FIG. 21 shows a structure of respective layers according to order for manufacturing a portion of a pixel circuit from among a lower panel layer of a light emitting display device, according to an embodiment.

FIG. 22 shows a structure of respective layers according to order for manufacturing a portion of a pixel circuit from among a lower panel layer of a light emitting display device, according to an embodiment.

FIG. 23 shows a cross-sectional view of a display panel, according to an embodiment.

FIG. 24 shows a cross-sectional view of a display panel, according to another embodiment.

FIG. 25 shows a graph of transmittance with respect to wavelengths of a color filter, according to an embodiment.

FIG. 26 shows a cross-sectional view of a light emitting display device, according to an embodiment.

FIG. 27 shows a cross-sectional view of a display panel, according to another embodiment.

FIG. 28 shows a cross-sectional view of a light emitting display device, according to still another embodiment.

### DETAILED DESCRIPTION

The invention will be described more fully hereinafter with reference to the accompanying drawings, in which embodiments of the invention are shown. As those skilled in the art would realize, the described embodiments may be modified in various different ways, all without departing from the spirit or scope of the invention.

The drawings and description are to be regarded as illustrative in nature and not restrictive, and like reference numerals designate like elements throughout the specification.

The size and thickness of each configuration shown in the drawings are arbitrarily shown for better understanding and ease of description, but the invention is not limited thereto. The thicknesses of layers, films, panels, regions, etc., are enlarged for clarity. For ease of description, the thicknesses of some layers and areas are exaggerated.

It should be understood that when an element such as a layer, film, region, or substrate is referred to as being “on” another element, it can be directly on the other element or intervening elements may also be present. In contrast, when an element is referred to as being “directly on” another element, there are no intervening elements present. It should be understood that when an element such as a layer, film, region, or substrate is referred to as being “on” another element, it can be directly on the other element or intervening elements may also be present.

Unless explicitly stated to the contrary, the word “comprise,” and variations such as “comprises” and “comprising,” should be understood to imply the inclusion of stated elements but not the exclusion of any other elements.

The phrase “in a plan view” means viewing an object portion from the top, and the phrase “in a cross-sectional view” means viewing a cross-section of which the object portion is perpendicularly cut from the side.

When it is stated that a part is “connected (in contact with, coupled)” to another part, the part may be “directly connected” to the other element, may be “connected” to the other part through a third part, or may be connected to the other part physically or electrically, and they may be referred to by different titles depending on positions or functions, but they may be substantially integrated into one body.

When parts such as wires, layers, films, regions, plates, or constituent elements are described as extending in the “first direction or the second direction,” this not only signifies a straight-line shape running straight in a corresponding direction, but also includes a structure generally extending in the first direction or the second direction, a structure bent on a predetermined portion, a zigzag-shaped structure, or a structure including a curved structure.

Electronic devices (e.g., mobile phones, TVs, monitors, laptop computers, etc.,) including the display device and the display panel described in the present specification or the electronic devices including the display device and the display panel manufactured by a manufacturing method described in the specification are not excluded from the claimed range of the present specification.

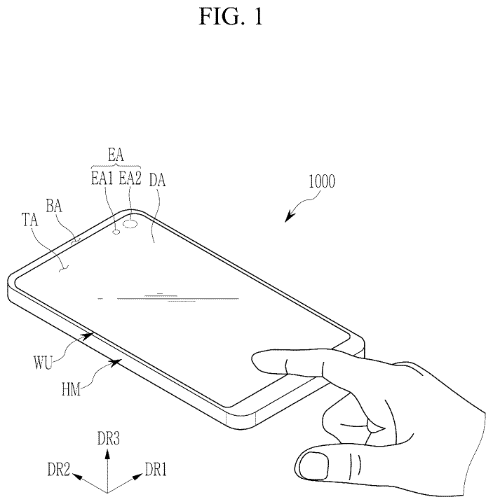

A structure of a display device will now be described with reference to FIG. 1 to FIG. 3.

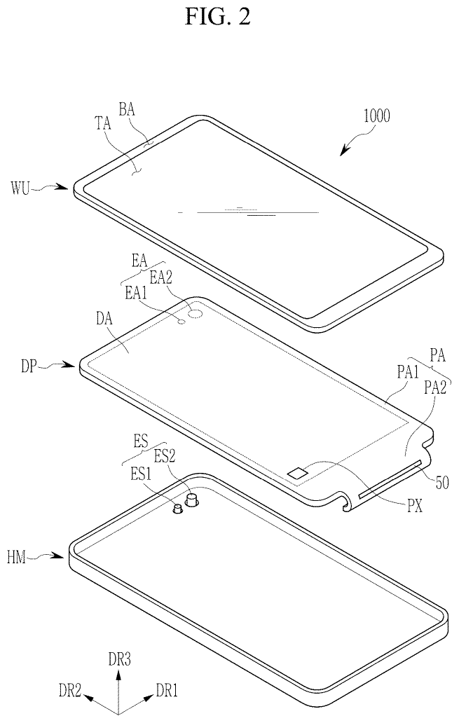

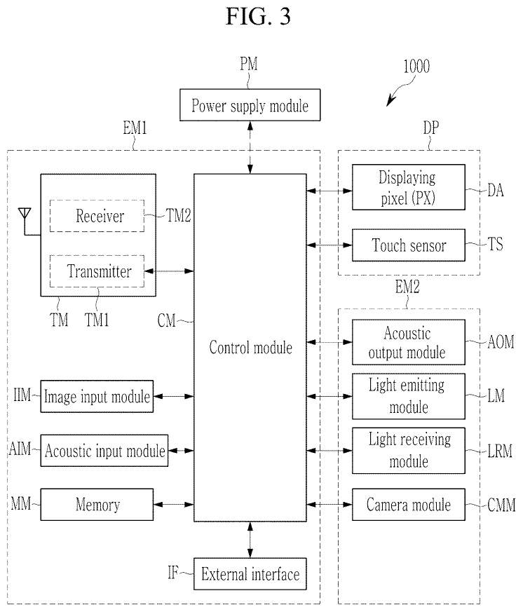

FIG. 1 shows a perspective view on a using state of a display device, according to an embodiment, FIG. 2 shows an exploded perspective view of a display device, according to an embodiment, and FIG. 3 shows a block diagram of a display device, according to an embodiment.

In an embodiment and referring to FIG. 1, the display device 1000 represents a device for displaying videos or still images, and it may be used as a display screen for portable electronic devices such as mobile phones, smartphones, tablet personal computers (PC), mobile communication terminals, electronic organizers, electronic books, portable multimedia players (PMP), global positioning systems, or ultramobile PCs (UMPC), and also for various products such as televisions, laptops, monitors, advertisement boards, or the Internet of Things (IOT). The display device 1000 may be used on wearable devices such as smart watches, watch phones, glasses-type displays, or head-mounted displays (HMD). The display device 1000 may be used as a dashboard of a vehicle, a center information display (CID) disposed on a center fascia or a dashboard of a vehicle, a room mirror display replacing a side-view mirror of a vehicle, and a display disposed on a rear surface of a front seat for entertainment for a back seat of a vehicle. FIG. 1 shows the display device 1000 being used as a smartphone, for better comprehension and ease of description.

In an embodiment, the display device 1000 may display images to a displaying side directed in parallel to a first direction DR1 and a second direction DR2 toward a third direction DR3. The displaying side for displaying images may correspond to a front surface of the display device 1000 and may correspond to a front surface of the cover window WU. The images may include videos and still images.

In an embodiment, front surfaces (or upper surfaces) and rear surfaces (or lower surfaces) of respective layers are defined with reference to the image displaying direction. The front surface and the rear surface may oppose each other in the third direction DR3, and normal-line directions of the front surface and the rear surface may be directed parallel to the third direction DR3. A spaced distance between the front surface and the rear surface in the third direction DR3 may correspond to a thickness of the display panel DP in the third direction DR3.

In an embodiment, the display device 1000 may sense a user input (refer to a hand in FIG. 1) applied from the outside. The user input may include various types of external inputs such as parts of the user's body, light, heat, or pressure. In an embodiment, the user input is shown to be a hand of the user applied to the front surface. However, the invention is not limited thereto. The user input may be provided in various forms, and the display device 1000 may sense the user input applied to the lateral side or the rear surface of the display device 1000 according to the structure of the display device 1000.

In an embodiment and referring to FIG. 1 and FIG. 2, the display device 1000 may include a cover window WU, a housing HM, a display panel DP, and an optical element ES. In an embodiment, the cover window WU and the housing HM may be combined to configure an exterior of the display device 1000.

In an embodiment, the cover window WU may include an insulation panel. For example, the cover window WU may be made of glass, plastic, or a combination thereof.

The front surface of the cover window WU may define the front surface of the display device 1000. A transmission area TA may be an optically transparent region. For example, the transmission area TA may have visible ray transmittance of equal to or greater than about 90%.

In an embodiment, a blocking area BA may define a shape of the transmission area TA and may be disposed near the transmission area TA and may surround the transmission area TA. The blocking area BA may have relatively lower light transmittance than the transmission area TA. The blocking area BA may include an opaque material for blocking light and may have a predetermined color. The blocking area BA may be defined by a bezel layer provided in addition to a transparent substrate for defining the transmission area TA or it may be defined by an ink layer inserted into or colored by the transparent substrate.

In an embodiment, the display panel DP may include a display pixel PX for displaying images and a driver 50, where the display pixel PX may be disposed in a display area DA and a component area EA. The display panel DP may include a front surface including a display area DA and a peripheral area PA. The display area DA and the component area EA include pixels and display images, a touch sensor is disposed on upper sides of the display area DA and the component area EA in the third direction DR3 of the pixel, and the display area DA and the component area EA may thus sense external inputs.

In an embodiment, the transmission area TA of the cover window WU may at least partly overlap the display area DA of the display panel DP and the component area EA. For example, the transmission area TA may overlap the entire sides of the display area DA and the component area EA, or may overlap at least part of the display area DA and the component area EA. Hence, the user may see the images through the transmission area TA or may provide external inputs based on the images. However, the invention is not limited thereto. For example, the region in which images are displayed may be separated from the region in which external inputs are sensed.

In an embodiment, the peripheral area PA of the display panel DP may at least partially overlap the blocking area BA of the cover window WU, where the peripheral area PA may be covered by the blocking area BA. The peripheral area PA may be disposed near the display area DA, and may surround the display area DA. The peripheral area PA may display no images, and a driving circuit for driving the display area DA or driving wires may be disposed therein. The peripheral area PA may include a first peripheral area PA1 disposed outside the display area DA and a second peripheral area PA2 including the driver 50, connection wires, and a bending region. In an embodiment of FIG. 2, the first peripheral area PA1 may be disposed on a third side of the display area DA, and the second peripheral area PA2 may be disposed on another side of the display area DA.

In an embodiment, the display panel DP may be assembled in a flat state so that the display area DA, the component area EA, and the peripheral area PA face the cover window WU. However, the invention is not limited thereto. A predetermined portion of the peripheral area PA of the display panel DP may be bent. Part of the peripheral area PA may face the rear surface of the display device 1000 so the blocking area BA seen on the front surface of the display device 1000 is reduced, and in FIG. 2, the second peripheral area PA2 may be bent to be disposed on the rear surface of the display area DA and assembled.

In an embodiment, the component area EA of the display panel DP may include a first component area EA1 and a second component area EA2, where the first component area EA1 and the second component area EA2 may be at least partially surrounded by the display area DA. The first component area EA1 and the second component area EA2 are shown to be spaced apart from each other, and without being limited thereto, at least part thereof may be connected to each other. The first component area EA1 and the second component area EA2 may represent regions below which optical elements (refer to ES of FIG. 2; also referred to as a component) using infrared rays, visible rays, or sound are disposed.

In an embodiment, the display area (DA, also referred to as a main display area) and the component area EA may include light emitting diodes, and pixel circuits for generating light emitting currents and transmitting the same to the light emitting diodes. Here, one light emitting diode and one pixel circuit may configure a pixel PX. One pixel circuit and one light emitting diode may be formed on a one-to-one basis in the display area DA and the component area EA.

In an embodiment, the first component area EA1 may include a transmitting portion through which light or/and sound transmits and a display unit including pixels. The transmitting portion may be disposed between adjacent pixels and may be made of a layer for transmitting light or/and sound. The transmitting portion may be disposed between adjacent pixels, and depending on embodiments, a layer through which light (e.g., visible rays) with a specific wavelength does not transmit may overlap the first component area EA1. The number of pixels (hereinafter, also referred to as resolution) per unit area of pixels (hereinafter referred to as normal pixels) included in the display area DA may correspond to the number of pixels per unit area of pixels (hereinafter, also referred to as first component pixels) included in the first component area EA1.

In an embodiment, the second component area EA2 may include a region (hereinafter, also referred to as a light transmitting region) made of a transparent layer to allow light to pass through, no conductive layer or semiconductor layer may be disposed in the light transmitting region, and a layer including a light blocking material—for example, a pixel defining layer and/or at least two color filters—may be formed to include an opening overlapping the position corresponding to the second component area EA2 and may not block light. The number of pixels per unit area of pixels (also referred to as second component pixels) included in the second component area EA2 may be less than the number of pixels per unit area of normal pixels included in the display area DA. As a result, a resolution of the second component pixel may be lower than the resolution of the normal pixel.

In an embodiment and referring to FIG. 3, the display panel DP may further include a touch sensor TS in addition to the display area DA including the display pixel PX. The display panel DP including the pixel PX for generating images may be visible to the user from the outside through the transmission area TA. Also, the touch sensor TS may be disposed on an upper portion of the pixel PX and may detect external inputs applied from the outside. The touch sensor TS may detect the external inputs provided to the cover window WU.

In an embodiment and referring to FIG. 2, the second peripheral area PA2 may include a bending portion. The display area DA and the first peripheral area PA1 may have a flat state directed substantially parallel to a plane defined by the first direction DR1 and the second direction DR2, and one side of the second peripheral area PA2 may extend from the flat state, pass through the bending portion, and have the flat state again. As a result, at least part of the second peripheral area PA2 may be bent and assembled to be disposed on the rear surface of the display area DA. When assembled, at least a part of the second peripheral area PA2 may overlap the display area DA in a plan view, and thereby the blocking area BA of the display device 1000 may be reduced. However, the invention is not limited thereto. For example, the second peripheral area PA2 may not be bent.

In an embodiment, the driver 50 may be mounted in the second peripheral area PA2 and may be mounted on the bending portion or may be disposed on either side of the bending portion. The driver 50 may be provided in the form of a chip.

In an embodiment, the driver 50 may be electrically connected to the display area DA and the component area EA and may transmit electrical signals to the pixels of the display area DA and the component area EA. For example, the driver 50 may provide data signals to the pixels PX disposed in the display area DA. In another embodiment, the driver 50 may include a touch driving circuit, and may be electrically connected to a touch sensor TS disposed in the display area DA and/or the component area EA. The driver 50 may include various circuits in addition to the above-described circuits or may be designed to provide various electrical signals to the display area DA.

In an embodiment, in the display device 1000, a pad portion may be disposed at an end of the second peripheral area PA2 and may be electrically connected to a flexible printed circuit board (FPCB) including a driving chip by the pad portion. The driving chip disposed on the flexible printed circuit board may include various driving circuits for driving the display device 1000 or a connector for supplying a power voltage. Depending on the embodiment, a rigid printed circuit board (PCB) may be used instead of the flexible printed circuit board.

In an embodiment, the optical element ES may be disposed below the display panel DP and may include a first optical element ES1 overlapping the first component area EA1 and a second optical element ES2 overlapping the second component area EA2. The first optical element ES1 may use infrared rays, and in this case, regarding the first component area EA1, a layer that does not transmit light, such as visible rays, may overlap the first component area EA1.

In an embodiment, the first optical element ES1 may be an electronic component using light or sound. For example, the first optical element ES1 may be a sensor that receives and uses light like an infrared sensor, a sensor that outputs and senses light or sound to measure a distance or recognize fingerprints, or a small lamp that outputs light, or a speaker that outputs sound. In the case of electronic components using light, it is possible to use light of various wavelength bands, such as visible light, infrared rays, and ultraviolet rays.

In an embodiment, the second optical element ES2 may be at least one of a camera, an infrared camera (IR camera), a dot projector, an infrared illuminator, and a time-of-flight sensor (ToF sensor).

In an embodiment and referring to FIG. 3, the display device 1000 may include a display panel DP, a power supply module PM, a first electronic module EM1, and a second electronic module EM2, where the display panel DP, the power supply module PM, the first electronic module EM1, and the second electronic module EM2 may be electrically connected to each other. FIG. 3 shows the display pixel and touch sensor TS disposed in the display area DA among the configuration of the display panel DP as an example.

In an embodiment, the power supply module PM may supply a power voltage that is necessary for the overall operation of the display device 1000. The power supply module PM may include a conventional battery module.

In an embodiment, the first electronic module EM1 and the second electronic module EM2 may include various types of functional modules for operating the display device 1000. The first electronic module EM1 may be directly mounted on the motherboard electrically connected to the display panel DP or it may be mounted on a separate substrate and may be electrically connected to the motherboard through a connector (not shown).

In an embodiment, the first electronic module EM1 may include a control module CM, a radio communication module TM, an image input module IIM, an acoustic input module AIM, a memory MM, and an external interface IF. Some of the modules may not be mounted on the motherboard, but may be electrically connected to the motherboard through a flexible printed circuit board connected thereto.

In an embodiment, the control module CM may control the overall operation of the display device 1000, where the control module CM may be a microprocessor. For example, the control module CM may activate or deactivate the display panel DP. The control module CM may control other modules such as the image input module IIM or the acoustic input module AIM based on the touch signal received from the display panel DP.

In an embodiment, the radio communication module TM may transmit/receive radio signals to/from other terminals using Bluetooth or Wi-Fi lines. The radio communication module TM may transmit/receive voice signals using a general communication line. The radio communication module TM may include a transmitter TM1 for modulating signals and transmitting the signals and a receiver TM2 for demodulating the received signals.

In an embodiment, the image input module IIM may process image signals and may convert them into image data displayable to the display panel DP. The acoustic input module AIM may receive an external sound signal by a microphone in a recording mode or a voice recognition mode and may convert it into electrical voice data.

In an embodiment, the external interface IF may serve as an interface connected to an external charger, a wired/wireless data port, a card socket (e.g., a memory card, a SIM/UIM card), etc.

In an embodiment, the second electronic module EM2 may include an acoustic output module AOM, a light emitting module LM, a light receiving module LRM, and a camera module CMM, at least some of which are referred to as optical elements ES and which may be disposed on the rear surface of the display panel DP as shown in FIG. 1 and FIG. 2. The optical element ES may include the light emitting module LM, the light receiving module LRM, and the camera module CMM. The second electronic module EM2 may be directly mounted on the motherboard, mounted on a separate substrate and electrically connected to the display panel DP through a connector (not shown), or electrically connected to the first electronic module EM1.

In an embodiment, the acoustic output module (AOM) may convert the acoustic data received from the radio communication module TM or the acoustic data stored in the memory MM and may output the same to the outside.

In an embodiment, the light emitting module LM may generate and output light. The light emitting module LM may also output infrared rays. For example, the light emitting module LM may include an LED device. For example, the light receiving module LRM may detect infrared rays. The light receiving module LRM may be activated when infrared rays above a predetermined level are detected. The light receiving module LRM may include a CMOS sensor. When the infrared rays generated in the light emitting module LM are output, they are reflected by an external subject (e.g., the user's finger or face), and the reflected infrared rays may be incident on the light receiving module LRM. The camera module CMM may photograph external images.

In an embodiment, the optical element ES may additionally include an optical sensor or a heat sensor. The optical element ES may detect an external subject received through the front surface or may provide sound signals such as voice to the outside through the front surface. Also, the optical element ES may include constituent elements and is not limited to any one embodiment.

In an embodiment and referring to FIG. 2, the housing HM may be combined with the cover window WU, where the cover window WU may be disposed on the front surface of the housing HM. The housing HM may be combined with the cover window WU to provide a predetermined accommodation space. The display panel DP and the optical element ES may be received in the predetermined accommodation space provided between the housing HM and the cover window WU.

In an embodiment, the housing HM may contain a material with relatively high rigidity. For example, the housing HM may include glass, plastic, or metal, or may include a plurality of frames and/or plates made of a combination thereof. The housing HM may stably protect the components of the display device 1000 accommodated in the internal space from external impacts.

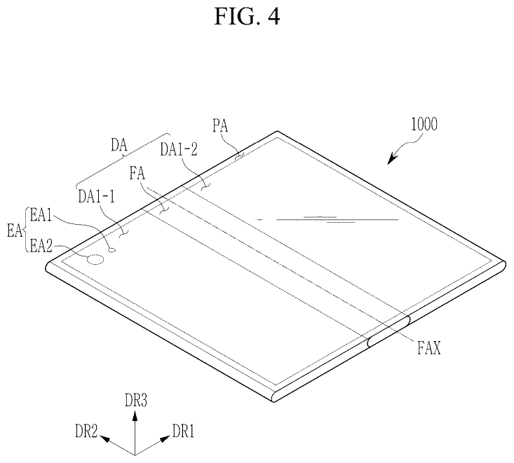

A structure of the display device 1000, according to another embodiment, will now be described with reference to FIG. 4.

FIG. 4 shows a perspective view of a light emitting display device, according to another embodiment.

Descriptions of the same configuration as the constituent elements described above will be omitted, and the embodiment of FIG. 4 shows a foldable display device having a structure in which the display device 1000 is folded through a folding axis FAX.

In an embodiment and referring to FIG. 4, the display device 1000 may be a foldable display device which may be folded outward or inward with respect to the folding axis FAX. When folded outward with respect to the folding axis FAX, the display surface of the display device 1000 may be disposed to the outside in the third direction DR3 respectively so that images may be displayed in both directions. When folded inward with respect to the folding axis FAX, the display surface may not be visible from the outside.

In an embodiment, the display device 1000 may include the display area DA, the component area EA, and the peripheral area PA. The display area DA may be divided into a first-1 display area DA1-1, a first-2 display area DA1-2, and a folding area FA. The first-1 display area DA1-1 and the first-2 display area DA1-2 may be disposed to the left and right respectively with respect to (or centered on) the folding axis FAX, and the folding area FA may be disposed between the first-1 display area DA1-1 and the first-2 display area DA1-2. When folded outward with respect to the folding axis FAX, the first-1 display area DA1-1 and the first-2 display area DA1-2 may be disposed on respective sides in the third direction DR3, and may bi-directionally display images. When folded inward with respect to the folding axis FAX, the first-1 display area DA1-1 and the first-2 display area DA1-2 may not be visible from the outside.

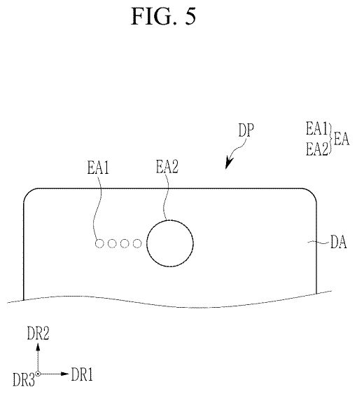

FIG. 5 shows a top plan view on an enlarged region of a light emitting display device, according to an embodiment.

FIG. 5 shows a portion of the light emitting display panel DP from among light emitting display devices, according to an embodiment, by using a display panel for a mobile phone.

In an embodiment, the display area DA may be disposed on the front surface of the light emitting display panel DP, and the component area EA may be disposed in the display area DA. The component area EA may include the first component area EA1 and the second component area EA2. In an embodiment, the first component area EA1 may be disposed near the second component area EA2. The first component area EA1 may be disposed to the left of the second component area EA2. The position and the number of the first component area EA1 may vary for each embodiment. The second optical element ES2 corresponding to the second component area EA2 may be a camera, and the first optical element ES1 corresponding to the first component area EA1 may be an optical sensor.

In an embodiment, light emitting diodes and pixel circuits for generating light emitting currents and transmitting the currents to the light emitting diodes may be formed in the display area DA. Here, one light emitting diode and one pixel circuit may configure a pixel PX. In the display area DA, one pixel circuit and one light emitting diode may be formed on a one-to-one basis. The display area DA may also be referred to as a normal display area hereinafter. FIG. 5 does not show the structure of the light emitting display panel DP given under a cutting-plane line, but the display area DA may be disposed under the cutting-plane line.

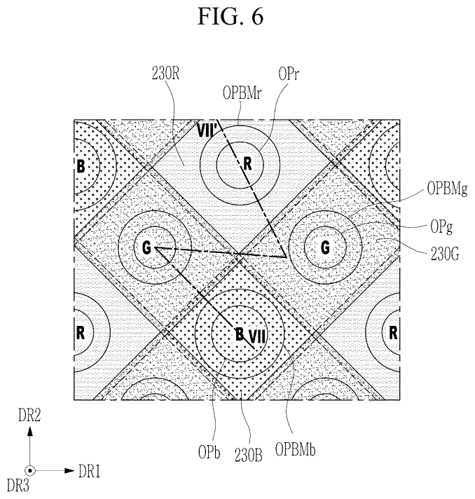

In an embodiment, the light emitting display panel DP may be largely divided into a lower panel layer and an upper panel layer. The lower panel layer may be the part where the light emitting diode and the pixel circuit constituting the pixel are disposed and may include an encapsulation layer (refer to 400 in FIG. 6) covering the same. That is, the lower panel layer covering from the substrate (refer to 110 of FIG. 6) to the encapsulation layer may include an anode, a pixel defining layer (refer to 380 of FIG. 6), an emission layer (refer to EML of FIG. 6), a spacer (refer to 385 of FIG. 6), a function layer (refer to FL of FIG. 6), and a cathode (refer to a cathode of FIG. 6), and may include an insulating layer disposed between the substrate and the anode, a semiconductor layer, and a conductive layer. The upper panel layer is disposed on an upper portion of the encapsulation layer, and may include a sensing insulating layer for sensing touches (refer to 501, 510, and 511 of FIG. 6) and sensing electrodes (refer to 540 and 541 of FIG. 6), and may include color filters (refer to 230R, 230G, and 230B of FIG. 6), and a planarization layer (refer to 550 of FIG. 6).

In an embodiment, the first component area EA1 may be made of a transparent layer to allow light to pass through, the conductive layer or the semiconductor layer may not be disposed thereon to allow light to pass through, the first component area EA1 may have a photosensor region on the lower panel layer, and may form an opening (also referred to as a photosensor region opening) on the position corresponding to the first component area EA1 in the pixel defining layer of the upper panel layer and the light blocking area of the color filter where at least two color filters overlap to not block light.

In an embodiment, when the photosensor region is disposed in the lower panel layer and there is no corresponding opening in the upper panel layer, it may be the display area DA and not the first component area EA1. One first component region EA1 may include a plurality of adjacent photosensor regions, and in this case, pixels disposed adjacent to the photosensor region may be included in the first component area EA1. When the first optical element ES1 corresponding to the first component area EA1 uses infrared rays instead of visible rays, the first component area EA1 may overlap the light blocking area of the color filter where at least two color filters overlap each other to block the visible rays.

In an embodiment, the second component area EA2 may include a second component pixel and a light transmitting region, and a space disposed between adjacent second component pixels may be the light transmitting region.

In an embodiment, although not shown in FIG. 5, a peripheral area may be further disposed outside the display area DA. FIG. 5 shows a display panel for a mobile phone, but the present embodiment may be applied to a display panel capable of disposing the optical element on the rear surface of the display panel, and may it be a flexible display device. In the case of a foldable display device from among flexible display devices, the positions of the second component area EA2 and the first component area EA1 may be formed at positions different from FIG. 5.

Structures of the normal display area and the first component area of the light emitting display panel DP according to an embodiment will now be described with reference to FIG. 6 to FIG. 9.

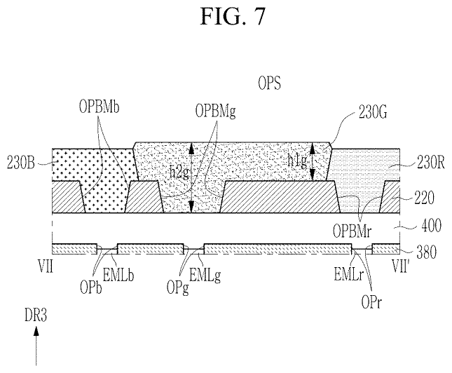

A structure of a normal display area will now be described with reference to FIG. 6 and FIG. 7.

FIG. 6 shows a top plan view on a portion of a normal display area of a light emitting display device, according to an embodiment, and FIG. 7 shows a cross-sectional view with respect to a cross-sectional line VII-VII′ of FIG. 6, according to an embodiment.

A planar structure of the normal display area will now be described with reference to FIG. 6.

FIG. 6 shows an embodiment of a top plan view of a portion of the normal display area of the light emitting display device seen from the front surface, showing color filters 230R, 230G, and 230B disposed on the upper panel layer, second openings OPBMr, OPBMg, and OPBMb (also referred to as second openings) of a light blocking layer 220 of FIG. 7 disposed on a lower portion of the color filter, and openings OPr, OPg, and OPb (also referred to as first openings) of a pixel defining layer 380 of FIG. 7.

In an embodiment, the color filters 230R, 230G, and 230B may have rhombus shapes, and the second openings OPBMr, OPBMg, and OPBMb of the light blocking layer may be covered with each one of the color filters 230R, 230G, and 230B.

In an embodiment, the light blocking layer may be disposed on a remaining portion excluding a portion where the second openings OPBMr, OPBMg, and OPBMb of the light blocking layer are formed in a plan view, and may be disposed on lower portions of the color filters 230R, 230G, and 230B in a cross-sectional view. The light blocking layer may form a region which is black and blocks light from being transmitted so that light may be transmitted through the portion where the second openings OPBMr, OPBMg, and OPBMb of the light blocking layer are formed. One of the color filters 230R, 230G, and 230B may be disposed in the second openings OPBMr, OPBMg, and OPBMb of the light blocking layer so light of one color may be transmitted.

In an embodiment, the openings OPr, OPg, and OPb of the pixel defining layer are disposed in the pixel defining layer, and may be partitioned by the pixel defining layer into the regions where the pixel defining layer is not disposed. The openings OPr, OPg, and OPb of the pixel defining layer may correspond to the light emitting region, and the light emitting layer included in the light emitting diode may be disposed in the openings OPr, OPg, and OPb of the pixel defining layer.

In an embodiment, the corresponding colors are divided into red (R), green (G), and blue (B) based on the light emitting layer of the light emitting diode and/or the color filters 230R, 230G, and 230B. The openings OPr, OPg, and OPb of the pixel defining layer and the second openings OPBMr, OPBMg, and OPBMb of the light blocking layer may be disposed near the red (R), green (G), and blue (B) light emitting regions of the normal light emitting regions.

In an embodiment, the openings OPr, OPg, and OPb of the pixel defining layer and the second openings OPBMr, OPBMg, and OPBMb of the light blocking layer may have circular shapes in a plan view, and they may have oval shapes, polygonal shapes, or chamfered shapes at polygonal corners. The openings OPr, OPg, and OPb of the pixel defining layer and the second openings OPBMr, OPBMg, and OPBMb of the light blocking layer may have different planar shapes.

In an embodiment, the openings OPr, OPg, and OPb of the pixel defining layer may be formed to have different areas for respective colors, and the openings OPr, OPg, and OPb of the pixel defining layer with the same colors may have the same area. The second openings OPBMr, OPBMg, and OPBMb of the light blocking layer may be formed to have different areas for respective colors, and the second openings OPBMr, OPBMg, and OPBMb of the light blocking layer with the same color may have the same area.

A cross-sectional structure with respect to the cross-sectional line of FIG. 6 will now be described with reference to FIG. 7.

FIG. 7 shows the pixel defining layer 380 and a structure of an upper portion thereof, according to an embodiment.

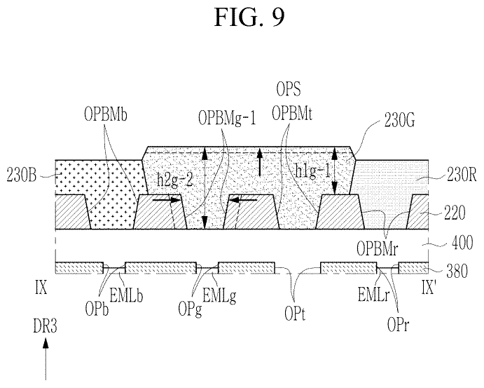

In an embodiment and referring to FIG. 7, no photosensor region first opening (refer to OPt of FIG. 9) is formed on a portion corresponding to the photosensor region OPS from among the pixel defining layer 380, differing from FIG. 9, and no photosensor region second opening (refer to OPBMt of FIG. 9) is formed on a portion of the light blocking layer 220 corresponding to the photosensor region OPS. However, depending on the embodiments, the photosensor region second opening of the light blocking layer 220 may not be formed, and the photosensor region first opening of the pixel defining layer 380 may be formed. When the photosensor region first opening of the pixel defining layer 380 is formed, there is no second opening corresponding to the photosensor region OPS from among the light blocking layer 220 so, as shown in FIG. 6, the photosensor region first opening may not be visible on the front surface.

The cross-sectional structure of FIG. 7 will now be described in detail.

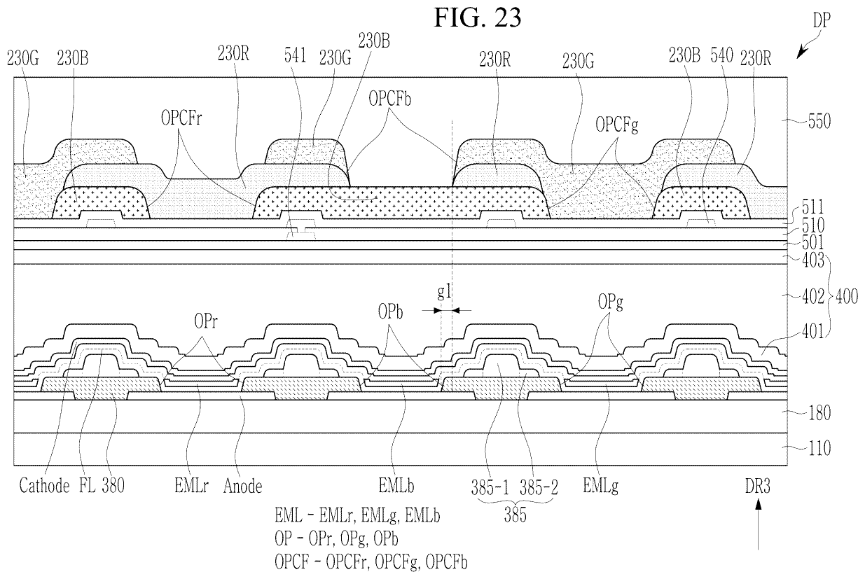

In an embodiment, the pixel defining layer 380 includes openings OPr, OPg, and OPb corresponding to the light emitting region. Light emitting layers EMLr, EMLg, and EMLb are disposed in the openings OPr, OPg, and OPb, respectively, of the pixel defining layer 380. An anode (refer to Anode of FIG. 23), a cathode (refer to Cathode of FIG. 23), and a function layer (refer to FL of FIG. 23) may be formed above/below the light emitting layers EMLr, EMLg, and EMLb to form a light emitting diode.

In an embodiment, the encapsulation layer 400 is disposed on the pixel defining layer 380 and the light emitting layers EMLr, EMLg, and EMLb. The encapsulation layer 400 may include at least one inorganic layer and at least one organic layer and may have a triple-layered structure including a first inorganic encapsulation layer, an organic encapsulation layer, and a second inorganic encapsulation layer. The encapsulation layer 400 may protect the light emitting layers EMLr, EMLg, and EMLb made of an organic material from moisture or oxygen input from the outside. Depending on the embodiment, the encapsulation layer 400 may include a structure in which an inorganic layer and an organic layer are sequentially further stacked.

In an embodiment, the light blocking layer 220 is disposed on the encapsulation layer 400, and second openings OPBMr, OPBMg, and OPBMb corresponding to the openings OPr, OPg, and OPb of the pixel defining layer 380 are formed in the light blocking layer 220. Since a portion corresponding to the photosensor region OPS is covered with the light blocking layer 220, no opening is formed. As a result, the light may not be transmitted to the photosensor region OPS in the normal display area so the optical element may not be disposed on the rear surface, and the operation for displaying images may be performed.

In an embodiment, the color filters 230R, 230G, and 230B may be formed on the light blocking layer 220, the respective color filters 230R, 230G, and 230B may be arranged in the second openings OPBMr, OPBMg, and OPBMb of the light blocking layer 220, respectively, and may overlap the adjacent color filters 230R, 230G, and 230B with different colors on the light blocking layer 220.

In an embodiment as shown in FIG. 7, when the blue color filter 230B, the red color filter 230R, and the green color filter 230G are sequentially formed, the green color filter 230G is formed last, and the green color filter 230G is disposed on an upper side, compared to the color filters with other colors.

In an embodiment, one color filter is disposed on the light blocking layer 220 corresponding to the photosensor region OPS, and the color filter formed last, that is, the green color filter 230G is disposed in an embodiment of FIG. 7. However, depending on embodiments, at least two of the color filters 230R, 230G, and 230B may overlap each other on the light blocking layer 220 corresponding to the photosensor region OPS.

FIG. 7 shows that the heights of the highest portion and the lowest portion of the green color filter 230G are h2g and h1g, and the heights will be compared to the first component area to be described later.

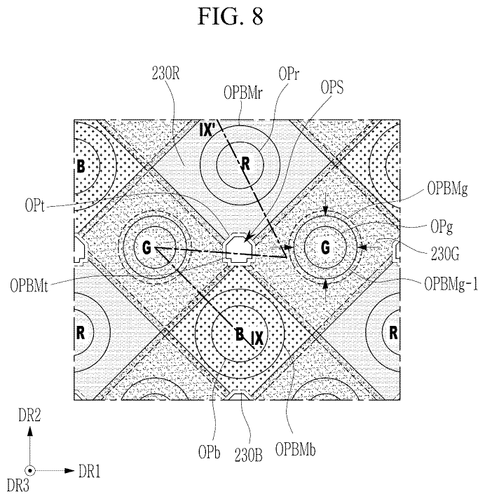

A structure of the first component area having the photosensor region OPS for transmitting light will now be described with reference to FIG. 8 and FIG. 9.

FIG. 8 shows a top plan view on a portion from among a first component area of a light emitting display device, according to an embodiment, and FIG. 9 shows a cross-sectional view with respect to a cross-sectional line IX-IX′ of FIG. 8, according to an embodiment.

FIG. 8 shows a top plan view of the first component area having a structure corresponding to FIG. 6.

Portions of FIG. 8 that are different from FIG. 6 will be mainly described.

In an embodiment, the photosensor region OPS for providing light to the optical element disposed on the rear surface may be disposed in the first component area, differing from the normal display area. At least one of the second openings of the light blocking layer disposed in the first component area has a smaller area than the second opening of the light blocking layer corresponding to the normal display area.

In an embodiment and referring to FIG. 8, the photosensor region second opening OPBMt of the light blocking layer 220 and the photosensor region first opening OPt of the pixel defining layer 380 are disposed so that the photosensor region OPS is not covered by the light blocking layer 220 to thus allow transmission of light. In detail, the photosensor region first opening OPt may have a greater area than the photosensor region second opening OPBMt, and FIG. 8 shows that the photosensor region first opening OPt is covered with the light blocking layer 220, which is marked with a dotted line. The cathode is disposed on the pixel defining layer 380 so when a boundary of the photosensor region first opening OPt is not covered by the light blocking layer 220, external light may be reflected on a boundary surface of the photosensor region first opening OPt and may be visible to a user. However, when the boundary of the photosensor region first opening OPt is covered by the light blocking layer 220, according to an embodiment, reflection of external light is not generated, which has the advantage of making it difficult for the user to confirm the existence of the photosensor region OPS.

In an embodiment, the second opening of one color from among the second openings in the first component area of FIG. 8 has a smaller area than the second opening of the same color in the normal display area.

In an embodiment, the area of the green second opening OPBMg-1 overlapped by the green color filter 230G formed last is narrower than the normal display area in the first component area of FIG. 8. The green second opening OPBMg disposed in the normal display area is shown with the dotted line, and the green second opening OPBMg-1 disposed in the first component area is shown with solid lines.

In an embodiment and referring to the cross-sectional structure of FIG. 9, the photosensor region second opening OPBMt of the light blocking layer 220 and the photosensor region first opening OPt of the pixel defining layer 380 are included in the photosensor region OPS. The light emitting layer may not be disposed in the photosensor region first opening OPt of the pixel defining layer 380. The photosensor region second opening OPBMt may be filled with one color filter, and it is filled with the green color filter 230G formed last from among the color filters 230R, 230G, and 230B.

In an embodiment, the green second opening OPBMg-1 of the first component area is formed to be narrower than the green second opening OPBMg of the normal display area. The green second opening OPBMg-1 of the first component area may have the width that is reduced by greater than about 0% and no more than about 30% compared to the green second opening OPBMg of the normal display area, and the width may be reduced by greater than about 0 μm and no more than about 2 μm.

In an embodiment, the second openings OPBMr, OPBMg, OPBMb, and OPBMg-1 of the normal display area and the first component area may have greater widths than the first openings OPr, OPg, and OPb disposed on the pixel defining layer 380. That is, depending on embodiments, when the width of the green second opening OPBMg-1 of the first component area is formed to be less than that of the green second opening OPBMg of the normal display area, the same width may be greater than that of the green opening OPg of the pixel defining layer 380.

In an embodiment, the green color filter 230G will now be mainly described with reference to FIG. 7 and FIG. 9.

FIG. 7 shows that the light blocking layer 220 is disposed on a portion corresponding to the photosensor region OPS, according to an embodiment, and FIG. 9 shows that the light blocking layer 220 is not formed on the portion corresponding to the photosensor region OPS, but the photosensor region second opening OPBMt is formed thereon, according to an embodiment. Hence, the green color filter 230G formed in the first component area of FIG. 9 is also formed in the photosensor region second opening OPBMt so when the green color filter 230G is formed with the same amount of the normal display area, the height of the green color filter 230G is reduced, which is a drawback. The height difference of the green color filter 230G may be seen as the change of color impressions.

Accordingly, in an embodiment, in the first component area of FIG. 9, the area of the green second opening OPBMg-1 of the light blocking layer 220, where the green color filter 230G is formed, is formed to have a narrower area than the green second opening OPBMg of the normal display area so when the green color filter 230G is formed with the same amount in the first component area and the normal display area, the difference in color impressions may be reduced or the user may not recognize the change of color impressions by making the height of the green color filter 230G the same or with a difference that is below a certain level. Here, the height of the green color filter 230G formed last in the first component area may differ by more than about −0.3 μm or about 0.2 μm compared to the height of the green color filter 230G in the normal display area.

In an embodiment and referring to an arrow in FIG. 9, the area of the green second opening OPBMg-1 of the light blocking layer 220 where the green color filter 230G is formed may be formed to be narrow in the first component area so the highest portion of the height of the green color filter 230G and the height of the lowest portion may be increased to be equal to the heights of the normal display area of FIG. 7—that is, h2g and h1g. FIG. 9 shows the height of the green color filter 230G with the dotted line to show the height difference that may be generated when the area of the green second opening OPBMg-1 of the light blocking layer 220 is formed to be about equal to that of the green second opening OPBMg of the normal display area, and the heights of the highest portion and the lowest portion of the green color filter 230G marked with the dotted line are respectively shown as h2g-2 and h1g-1. Therefore, by narrowing the area of the green second opening OPBMg-1 of the light blocking layer 220, the height of the green color filter 230G is increased from h2g-2 and h1g-1 to h2g and h1g to be thus kept about equal to the height of the green color filter 230G in the normal display area.

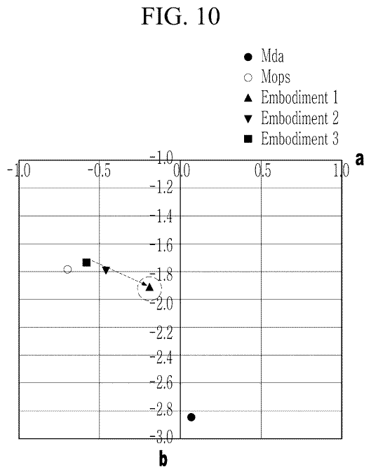

Changes of color impressions between various embodiments and comparative examples will now be described with reference to FIG. 10.

FIG. 10 shows a color coordinate on changes of color impressions of a light emitting display device, according to an embodiment.

In an embodiment as shown in FIG. 10, the color coordinate of 10 may be an SCI color coordinate, where a may represent red and green component values, and b may represent yellow and blue component values.

Referring to FIG. 10, Mda and Mops are actually measured color coordinate values, where Mda is a color coordinate value of the normal display area, according to an embodiment of FIG. 6 and FIG. 7, and Mops is the color coordinate value of the first component area according to a comparative example formed to have the same area as the second opening of the normal display area without reducing the area of the second opening, in contrast to FIG. 8 and FIG. 9. Embodiment 1, embodiment 2, and embodiment 3 are color coordinate values based on simulations, where embodiment 1 shows that the green color filters 230G of the normal display area and the first component area are formed to have the same height, embodiment 2 shows that the green color filter 230G of the first component area is formed to be lower than the normal display area by about 0.2 μm, and embodiment 3 shows that the green color filter 230G of the first component area is formed to be lower than the normal display area by about 0.3 μm. In an embodiment and referring to FIG. 10, the color impression Mops of the first component area according to a comparative example is much different from the color impression Mda of the normal display area, and it is found that the difference in color impressions is relatively reduced in embodiments 1 to 3. In detail, it may be found that as the height difference of the green color filter 230G in the normal display area and the first component area decreases from about −0.3 μm to about −0.2 μm and about 0 μm, it approaches the color impression Mda of the normal display area. Referring to FIG. 10, the a-axis direction indicates the green component value so when the height of the green color filter 230G in the normal display area and the first component area is formed to be slightly greater than that of the green color filter 230G of the normal display area, it is expected to further move to the right in the a-axis direction, and hence, depending on the embodiments, the height of the green color filter 230G in the first component area may be greater than that of the green color filter 230G in the normal display area by no more than about 0.2 μm. Therefore, as described above, the height of the green color filter 230G in the first component area may be different from the height of the green color filter 230G in the normal display area by about equal to or greater than about −0.3 μm and about 0.2 μm.

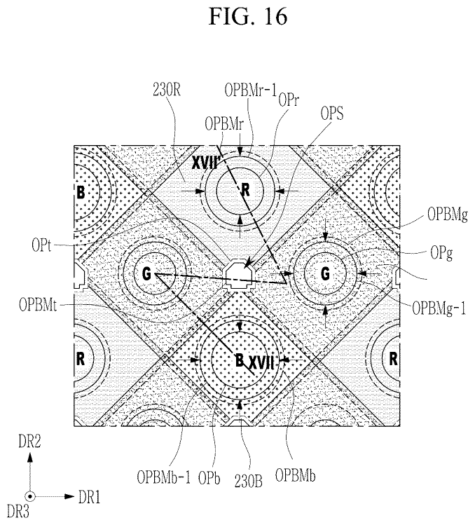

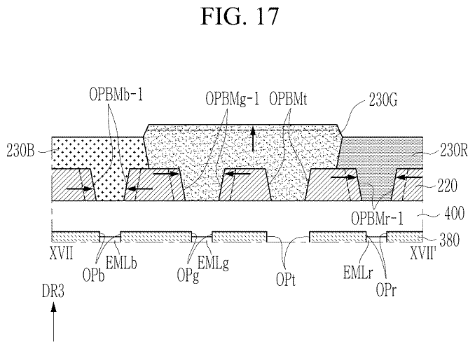

However, as shown in FIG. 10, there may be a difference between embodiment 1 and the color impression Mda of the normal display area, and a modification may be provided as shown in FIG. 16 and FIG. 17 to additionally reduce the difference.

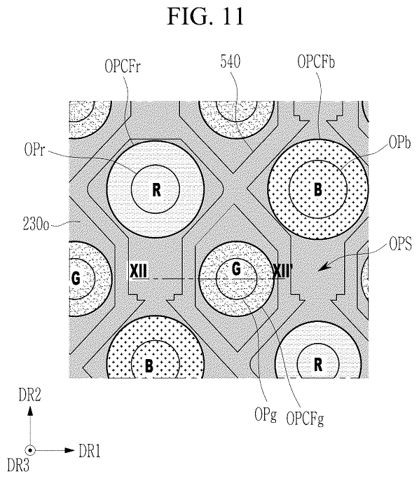

Another embodiment for reducing the difference in color impression in the normal display area and the first component area will now be described with reference to FIG. 11 to FIG. 14, where FIG. 11 to FIG. 14 shows the embodiment in which the light blocking area is formed by overlapping at least two color filters instead of the light blocking layer.

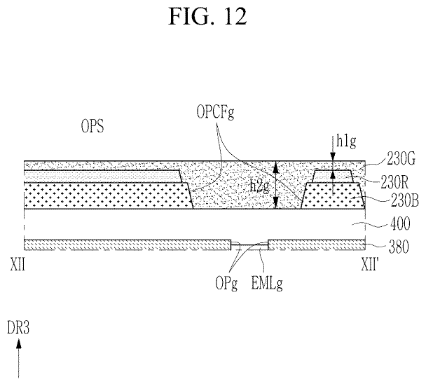

A structure of the normal display area will now be described with reference to FIG. 11 and FIG. 12, according to an embodiment.

FIG. 11 shows a top plan view on a portion from among a normal display area of a light emitting display device, according to another embodiment, and FIG. 12 shows a cross-sectional view with respect to a cross-sectional line XII-XII′ of FIG. 11, according to an embodiment.

A planar structure will now be described with reference to FIG. 11.

In an embodiment, FIG. 11 shows a plan view of a portion of the normal display area from among the light emitting display devices as seen from the front surface, showing a light blocking area 230o of the color filter disposed on the upper panel layer, second openings OPCFr, OPCFg, and OPCFb of the light blocking area of color filters, openings OPr, OPg, and OPb of the pixel defining layer, and a sensing electrode 540.

In an embodiment, the light blocking area 230o of the color filter is a region where at least two color filters overlap among the three color filters, representing a region that blocks light by replacing the black light blocking layer. Referring to FIG. 11, the light blocking area 230o of the color filter is marked with a dark color to indirectly show that light is blocked.

In an embodiment, the openings OPr, OPg, and OPb of the pixel defining layer are disposed in the pixel defining layer (see 380 in FIG. 12) and are partitioned by the pixel defining layer into regions where the pixel defining layer is not disposed. The openings OPr, OPg, and OPb (or first openings) corresponding to the light emitting region from among the openings of the pixel defining layer may correspond to the light emitting region—that is, the region in which the light emitting layer of the light emitting diode is disposed—and they are distinguished into red (R), green (G), and blue (B) in FIG. 11.

In an embodiment, the second openings OPCFr, OPCFg, and OPCFb of the light blocking area of color filters are other than the light blocking area 230o of the color filter, and may be the second openings OPCFr, OPCFg, and OPCFb (or second openings) in which the color filter of one color is disposed from among the color filters of three colors and which correspond to the light emitting region. The light blocking area 230o of the color filter may be disposed in the portion corresponding to the photosensor region OPS to block transmission of light in the normal display area.

In an embodiment, the sensing electrode 540 may be disposed at the lower portion of the light blocking area 230o of the color filter, so it may not be seen on the front surface of the actual light emitting display device, but is shown in FIG. 11 to show the planar position. Referring to FIG. 11, the sensing electrode 540 extends in a diagonal direction and is disposed in a region that does not overlap the second openings OPCFr, OPCFg, and OPCFb of the light blocking area of color filters. The sensing electrode 540 may be divided into two electrically separated electrodes.

In an embodiment and referring to FIG. 11, the openings OPr, OPg, and OPb of the pixel defining layer and the second openings OPCFr, OPCFg, and OPCFb of the light blocking area of color filters are disposed around the light emitting regions R, G, and B, and a peripheral portion of the photosensor region OPS is covered with the light blocking area 230o of the color filter.

In the embodiment of FIG. 11, the openings OPr, OPg, and OPb of the pixel defining layer and the second openings OPCFr, OPCFg, and OPCFb of the light blocking area 230o of color filters are shown to have circular shapes in a plan view, and they may have an oval shape, a polygonal shape, or chamfered corners of the polygon. The openings OPr, OPg, and OPb of the pixel defining layer and the second openings OPCFr, OPCFg, and OPCFb of the light blocking area 230o of color filters may have different planar shapes.

In the embodiment of FIG. 11, the openings OPr, OPg, and OPb of the pixel defining layer may have different areas for the respective colors, and the openings OPr, OPg, and OPb of the pixel defining layer with the same color may have the same area. The second openings OPCFr, OPCFg, and OPCFb of the light blocking area 230o of color filters may also have different areas for respective colors, and the second openings OPCFr, OPCFg, and OPCFb of the light blocking area 230o of color filters with the same color may have different areas.

A cross-sectional structure with respect to a cross-sectional line of FIG. 11 will now be described with reference to FIG. 12, according to an embodiment.

FIG. 12, which shows no sensing electrode shows an upper structure of the pixel defining layer 380.

In the embodiment of FIG. 12, the light blocking area (refer to 230o in FIG. 11) of the color filter may correspond to the region where the red color filter 230R, the green color filter 230G, and the blue color filter 230B overlap each other, and depending on the embodiment, at least one of the three color filters may not overlap.

In an embodiment, the red color filter 230R is disposed in the red second opening OPCFr of the light blocking area of color filters, the green color filter 230G is disposed in the green second opening OPCFg, and the blue color filter 230B is disposed in the blue second opening OPCFb. The second openings OPCFr, OPCFg, and OPCFb in the light blocking area of color filters may be defined as openings disposed in the color filter of another color disposed at the bottom. The red second opening OPCFr and the green second opening OPCFg may correspond to the openings disposed in the blue color filter 230B, and the blue second opening OPCFb may correspond to the opening disposed in the red color filter 230R.

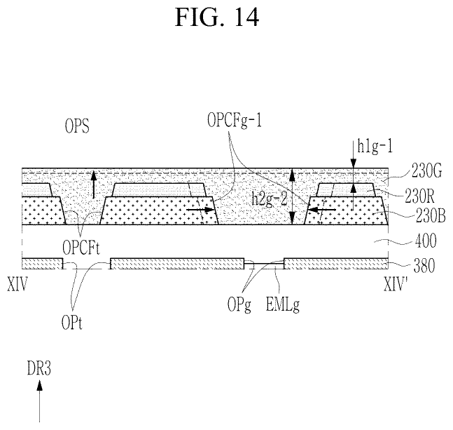

In an embodiment and referring to FIG. 12, the photosensor region first opening (refer to OPt of FIG. 14) is not formed in the portion corresponding to the photosensor region OPS from among the pixel defining layer 380, differing from FIG. 14, in the photosensor region OPS, and the photosensor region second opening (refer to OPCFt of FIG. 14) is not formed in the portion corresponding to the photosensor region OPS from among the light blocking area 230o of the color filter. However, depending on the embodiment, the photosensor region second opening of the light blocking area 230o of the color filter may not be formed, but the photosensor region first opening of the pixel defining layer 380 may be formed. When the photosensor region first opening of the pixel defining layer 380 is formed, no opening corresponds to the photosensor region OPS from among the light blocking area 230o of the color filter so the photosensor region first opening may not be visible on the front surface as shown in FIG. 11.

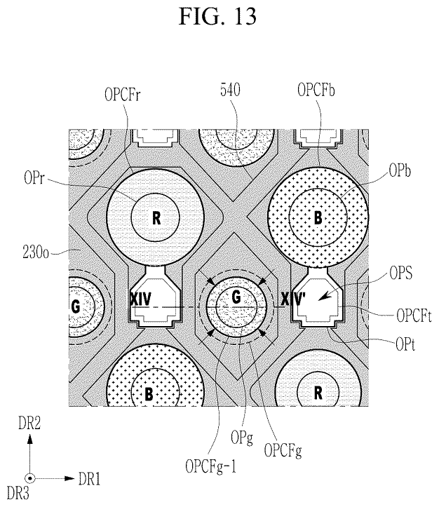

A structure of a first component area will now be described with reference to FIG. 13 and FIG. 14.

FIG. 13 shows a top plan view of a portion from among a first component area of a light emitting display device, according to an embodiment, and FIG. 14 shows a cross-sectional view with respect to a cross-sectional line XIV-XIV′ of FIG. 13, according to an embodiment.

A planar structure will now be described with reference to FIG. 13.

Portions in FIG. 13 which are different from those in FIG. 11 will now be mainly described.

In an embodiment, the photosensor region OPS for supplying light to the optical element disposed on the rear surface is disposed in the first component area, differing from the normal display area. At least one of the second openings of the light blocking area 230o of color filters disposed in the first component area is formed to have a narrower area than the second opening of the light blocking layer corresponding to the normal display area.

In an embodiment, the photosensor region second opening OPCFt is disposed in the light blocking area 230o of color filters so the photosensor region OPS is not covered by the light blocking area 230o of color filters and is seen on the front surface.

In an embodiment, the second opening of one color from among the second openings in the first component area has a narrower area than the second opening of the same color of the normal display area.

In an embodiment and in the first component area, the area of the green second opening OPCFg-1 overlapping the green color filter 230G formed last is formed narrower than the normal display area. For the purpose of comparison, the green second opening OPCFg of the normal display area is marked with the dotted line, and the green second opening OPCF-1 disposed in the first component area is marked with the solid line.

In an embodiment and referring to the cross-sectional structure of FIG. 14, the photosensor region second opening OPCFt of the light blocking area 230o of color filters is disposed in the photosensor region OPS, and the photosensor region first opening OPt of the pixel defining layer 380 is disposed therein. The photosensor region second opening OPCFt may be filled with the color filter of one color, and referring to FIG. 14, the photosensor region second opening OPCFt is filled with the green color filter 230G, which is the last to be formed from among the color filters 230R, 230G, and 230B.

In detail, in an embodiment, the photosensor region first opening OPt may have a greater area than the photosensor region second opening OPCFt. The cathode is disposed on the pixel defining layer 380 so when the boundary of the photosensor region first opening OPt is not covered by the light blocking area 230o of color filters, external light may be reflected on the boundary surface of the photosensor region first opening OPt and may be visible to the user. However, when the boundary of the photosensor region first opening OPt is covered with the light blocking area 230o of color filters, according to an embodiment, reflection of external light is not generated and the user may have difficulty in confirming the existence of the photosensor region OPS, which is a merit.

In an embodiment and referring to the cross-sectional structure of FIG. 14, the green second opening OPCFg-1 of the light blocking area 230o of color filters is formed with a narrower width than the green second opening OPCFg of the normal display area. Here, the width of the green second opening OPCFg-1 in the first component area may be reduced by greater than about 0% and no more than about 30% compared to the green second opening OPCFg in the normal display area, and in numerical terms, the width may be reduced by greater than about 0 μm and no more than about 2 μm.

In an embodiment and in detail, the second openings OPCFr, OPCFg, OPCFb, and OPCFg-1 in the normal display area and the first component area may have a greater width than the first openings OPr, OPg, and OPb disposed on the pixel defining layer 380. That is, depending on the embodiment, when the green second opening OPCFg-1 in the first component area has a narrower width than the green second opening OPCFg in the normal display area, it may have a greater width than the green opening OPg of the pixel defining layer 380.

The green color filter 230G will now be mainly described with reference to FIG. 14 and FIG. 12.

FIG. 12 shows that the light blocking area 230o of color filters is disposed on the portion that corresponds to the photosensor region OPS, according to an embodiment, and FIG. 14 shows that the photosensor region second opening OPBMt, not the light blocking area 230o of color filters, is disposed on the portion that corresponds to the photosensor region OPS, according to an embodiment. Therefore, the green color filter 230G formed in the first component area of FIG. 12 must also be formed in the photosensor region second opening OPBMt so when the green color filter 230G is formed in the same amount as the normal display area, the height of the lower surface of the green color filter 230G is reduced, which is a drawback. This height difference of the green color filter 230G may be seen as a change in color impression.

In an embodiment, the green second opening OPCFg-1 in the light blocking area 230o of color filters in which the green color filter 230G is formed has a smaller area than the green second opening OPCFg in the normal display area in the first component area of FIG. 14 so when the same amount of the green color filter 230G is formed in the first component area and the normal display area, the height of the green color filter 230G may be the same or may have a difference below a predetermined degree, thus reducing the difference in color impression or preventing the user from detecting changes of the color impressions. The height of the green color filter 230G, which is formed last in the first component area, may be different from the height of the green color filter 230G in the normal display area by about equal to or greater than about −0.3 μm and about 0.2 μm.

In an embodiment and referring to the arrow in FIG. 14, the area of the green second opening OPCFg-1 in the light blocking area 230o of color filters in which the green color filter 230G is formed may be formed to be narrow in the first component area so the heights of the highest portion and the lowest portion from among the heights of the green color filter 230G may be increased to be about equal to the heights of the normal display area of FIG. 12—that is, h2g and h1g. FIG. 14 shows the height of the green color filter 230G with the dotted line to show the height difference that may be generated when the area of the green second opening OPCFg-1 in the light blocking area 230o of color filters may be about equal to that of the green second opening OPCFg in the normal display area, and the heights of the highest portion and the lowest portion of the green color filter 230G marked with the dotted line are respectively shown as h2g-2 and h1g-1.Therefore, by narrowing the area of the green second opening OPCFg-1 in the light blocking area 230o of color filters, the heights of the green color filter 230G may be increased from h2g-2 and h1g-1 to h2g and h1g to thus control the heights to be about equal to the height of the green color filter 230G in the normal display area.

The embodiment of FIG. 11 to FIG. 14 may have the effect of reducing the difference in color impression in a similar way to FIG. 10.

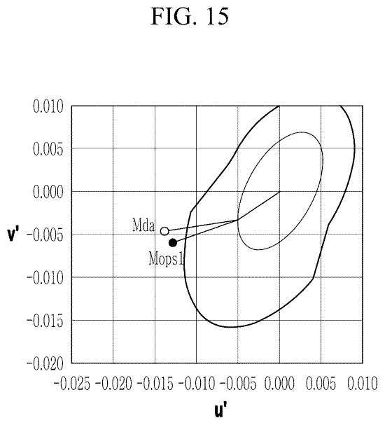

In the embodiment of FIG. 6 to FIG. 10 and the embodiment of FIG. 11 to FIG. 14, the color impression may be adjusted for one color so that luminance ratios on the sides may be degraded, and the color impression on the sides may also be changed. Particularly, the green color was changed in the previous embodiment so a reddish or blueish phenomenon may appear on the side, which is shown in FIG. 15.

FIG. 15 shows a color coordinate on a difference of color impressions of a light emitting display device, according to a comparative example.

FIG. 15 shows an embodiment of a CIE 1976 color coordinate, and in detail, Mda and Mops1 are actually measured color coordinate values, Mda is a color coordinate value of the normal display area, and Mops1 is a color coordinate value, according to a comparative example, formed to have the same area of the second opening in the normal display area without reducing the area of the second opening in the first component area.

FIG. 15 shows that the color coordinates of the normal display area and the first component area are recognized to have different color impressions when approaching to the side in the light emitting display device, according to a comparative example.

In an embodiment, the first component area may be formed as shown in FIG. 16 and FIG. 17 to remove the difference in color impressions generated on the side.

FIG. 16 shows a top plan view on a portion from among a first component area of a light emitting display device, according to another embodiment, and FIG. 17 shows a cross-sectional view with respect to a cross-sectional line XVII-XVII′ of FIG. 16.

FIG. 16 and FIG. 17 are modified embodiments of FIG. 8 and FIG. 9 and may have the structure shown in FIG. 6 and FIG. 7 as the normal display area.

In an embodiment and referring to FIG. 16 and FIG. 17, in contrast to FIG. 8 and FIG. 9, at least two of the second openings of the light blocking layer disposed in the first component area may have a narrower area than the second opening of the light blocking layer corresponding to the normal display area, and the second openings of all colors may have narrower areas than the second opening of the light blocking layer corresponding to the normal display area.

In detail, in an embodiment and referring to FIG. 16, the second openings OPBMr-1, OPBMg-1, and OPBMb-1 disposed near the photosensor region OPS have narrower areas than the second openings OPBMr, OPBMg, and OPBMb of the same color in the normal display area.

The second openings OPBMr-1, OPBMg-1, and OPBMb-1 in the first component area of FIG. 16 are marked with a solid line, and the second openings OPBMr, OPBMg, and OPBMb in the normal display area are marked with a dotted line so that they may be compared to each other.

In an embodiment and referring to the cross-sectional structure of FIG. 17, the photosensor region OPS includes the photosensor region second opening OPBMt of the light blocking layer 220 and the photosensor region first opening OPt of the pixel defining layer 380 and is covered with the green color filter 230G formed last from among the color filters 230R, 230G, and 230B.

In an embodiment and referring to the cross-sectional structure of FIG. 17, the second openings OPBMr-1, OPBMg-1, and OPBMb-1 in the first component area are formed to have narrower widths than the second openings OPBMr, OPBMg, and OPBMb in the normal display area. The widths of the second openings OPBMr-1, OPBMg-1, and OPBMb-1 in the first component area may be reduced by greater than about 0% and no more than about 30%, compared to the second openings OPBMr, OPBMg, and OPBMb in the normal display area, and numerically by greater than about 0 μm and no more than about 2 μm. The ratio by which the area or width of the second openings OPBMr-1 and OPBMb-1 corresponding to the blue color filter 230B and the red color filter 230R formed first is reduced may be substantially equal to the ratio by which the area or width of the green second opening OPBMg-1 corresponding to the green color filter 230G formed last is reduced. The reduced ratio represents the reduced ratio of the area or width of the second opening in the first component area with respect to the normal display area. As a result, the color impression of the three colors may be changed to be constant. Depending on the embodiments, the ratio reduced by errors may be different within the range of no more than about 5%.

In detail, in an embodiment, the second openings OPBMr, OPBMg, OPBMb, OPBMr-1, OPBMg-1, and OPBMb-1 in the normal display area and the first component area may be formed to have greater widths than the first openings OPr, OPg, and OPb disposed in the pixel defining layer 380. That is, depending on an embodiment, when the second openings OPBMr-1, OPBMg-1, and OPBMb-1 in the first component area have narrower widths than the second openings OPBMr, OPBMg, and OPBMb in the normal display area, they may be formed to have greater widths than the openings OPr, OPg, and OPb of the pixel defining layer 380.

The green color filter 230G will now be mainly described with reference to FIG. 17.

In an embodiment and referring to FIG. 17, not the light blocking layer 220 but the photosensor region second opening OPBMt is disposed in the portion corresponding to the photosensor region OPS to thus fill the photosensor region second opening OPBMt with the green color filter 230G. Therefore, when the green color filter 230G is formed with the same amount of the normal display area, the height of the green color filter 230G in the first component area may be reduced and this may be seen as the change of color impression. As in the embodiments of FIG. 16 and FIG. 17, when the area of the green second opening OPBMg-1 of the light blocking layer 220 is formed to have a narrower area than the green second opening OPBMg in the normal display area, and the same amount of the green color filter 230G is formed in the first component area and the normal display area, the height of the green color filter 230G may be formed to be the same or have a difference that is less than a predetermined level, thus reducing the difference of color impressions or preventing the user from seeing the change of color impressions. When formed as described above, the green color impression is changed, so the difference of color impressions may be generated when considering the red and blue colors, and this may be seen as the greater difference of color impression (see FIG. 15) toward the side.

In an embodiment and as shown in FIG. 16 and FIG. 17, when the red second opening OPBMr-1 of the light blocking layer 220 is formed to have a narrower area than the red second opening OPBMr in the normal display area, and the blue second opening OPBMb-1 of the light blocking layer 220 is formed to have a narrower area than the blue second opening OPBMb in the normal display area, the general color impression may be changed to be constant. As a result, the change of color impressions in the normal display area and the first component area may not be generated or may be reduced, and particularly, the color impression on the side may generate no difference or may reduce the difference. The heights of the color filters 230R, 230G, and 230B of the respective colors formed in the first component area may have the difference by about equal to or greater than about −0.3 μm and about 0.2 μm, compared to the heights of the color filters 230R, 230G, and 230B of the corresponding colors in the normal display area.

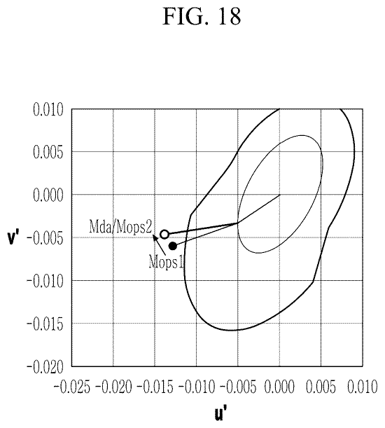

Changes of color impressions according to an embodiment of FIG. 16 and FIG. 17 will now be described with reference to FIG. 18.

FIG. 18 shows a color coordinate on changes of color impressions of a light emitting display device, according to an embodiment of FIG. 16 and FIG. 17.

In an embodiment, FIG. 18 shows the same color coordinate as that of FIG. 15, where Mda is the color coordinate value of the normal display area, Mops1 is the color coordinate value according to a comparative example formed to have the same area as the second opening in the normal display area without reducing the area of the second opening in the first component area, and Mops2 is the color coordinate value of the first component area, according to the embodiment of FIG. 16 and FIG. 17.

In an embodiment and referring to FIG. 18, as shown in FIG. 16 and FIG. 17, the change of color impressions changed when the second openings OPBMr-1, OPBMg-1, and OPBMb-1 in the first component area are formed to have narrower widths than the second openings OPBMr, OPBMg, and OPBMb in the normal display area is marked with the arrow, and for optimization, they may be set to be the equal to the color coordinate value Mda of the normal display area such as Mops2.

For this purpose, in an embodiment, the ratio for reducing the area or width of the second openings OPBMr-1 and OPBMb-1 corresponding to the blue color filter 230B and the red color filter 230R formed first may be formed to be substantially equal to the ratio for reducing the area or width of the green second opening OPBMg-1 corresponding to the green color filter 230G formed last. The reducing ratio represents the reducing ratio of the area or width of the second opening in the first component area with respect to the normal display area.

As a result, the user may not recognize the difference of color impressions between the normal display area and the first component area in one light emitting display device, and particularly, it may be difficult to recognize the difference of color impressions on the side.

It has been described in the embodiments of FIG. 16 and FIG. 17 that the area of the second openings OPBMr-1 and OPBMb-1 in the first component area corresponding to another color (blue and/or red) other than the first color (green) is formed to be narrower than the area of the second openings OPBMr and OPBMb corresponding to another color in the normal display area, with reference to the embodiment in which the second opening is formed in the light blocking layer 220. Depending on embodiments, the second opening of one of the red color and the blue color may formed to be narrow in the first component area.

However, depending on embodiments, as in FIG. 11 to FIG. 14, the light blocking layer 220 may not be included, the light blocking area may be formed by overlapping at least two color filters, and the second opening may be formed in the light blocking area. As shown in FIG. 16 and FIG. 17, the area of the second opening in the first component area corresponding to another color (blue and/or red) other than the first color (green) may be formed to be narrower than the area of the second opening corresponding to another color of the normal display area. Depending on an embodiment, the second opening of one of the red color and the blue color may formed to be narrow in the first component area.

In an embodiment, the light emitting display device has been described with reference to the pixel defining layer 380 and the upper structure thereof.

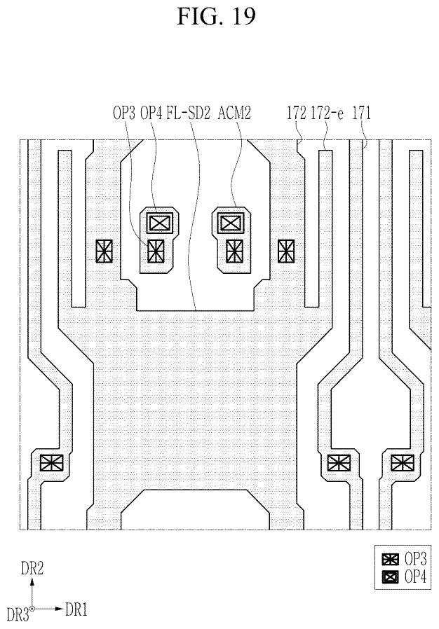

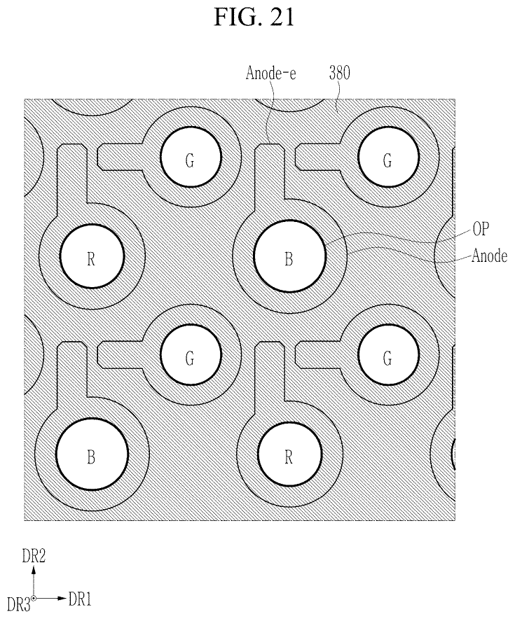

A structure of a lower panel layer in the light emitting display device will now be described with reference to FIG. 19 to FIG. 22.

FIG. 19 to FIG. 22 show the structure of each layer according to the manufacturing order of a portion of a pixel circuit from among a lower panel layer of a light emitting display device, according to an embodiment.

In an embodiment, the structure shown in FIG. 19 to FIG. 22 may be formed in the normal display area and the first component area.

A detailed planar structure of a pixel formed in the display area DA will now be described with reference to FIG. 19 to FIG. 22, and each pixel, according to an embodiment, includes a photosensor region OPS.

FIG. 19 shows a structure of a second data conductive layer in a pixel circuit, according to an embodiment.

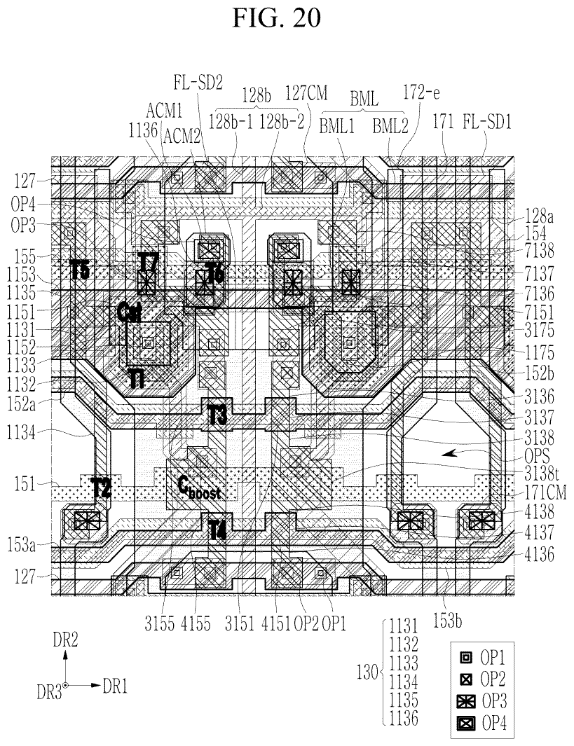

Gate conductive layers, a semiconductor layer, and a first data conductive layer may be disposed on a lower portion of the second data conductive layer, and a detailed structure will be described later with reference to FIG. 20.

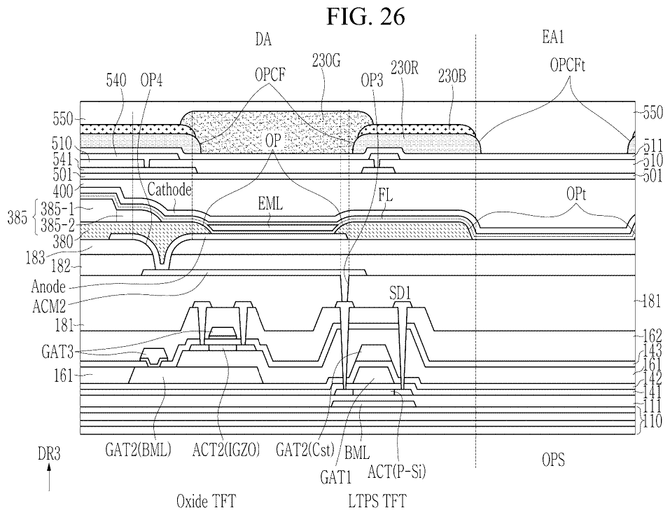

In an embodiment and referring to FIG. 19, a lower organic layer opening OP3 is disposed in a first organic layer (refer to 181 of FIG. 26) disposed on the lower portion of the second data conductive layer. The lower organic layer opening OP3 may overlap a connector (refer to 171 CM of FIG. 20), an anode connecting electrode ACM1, and an extension FL-SD1 disposed on the first data conductive layer and may expose each of them.

In an embodiment, a second data conductive layer including a data line 171, a driving voltage line 172, and an anode connecting electrode ACM2 may be disposed on the first organic layer (refer to 181 of FIG. 26). A second organic layer (refer to 182 of FIG. 26) and a third organic layer (refer to 183 of FIG. 26) are disposed on the second data conductive layer, and an anode connecting opening OP4 is formed in the second organic layer 182 and the third organic layer 183. The anode connecting electrode ACM2 may be electrically connected to the anode through the anode connecting opening OP4.

In an embodiment and referring to FIG. 19, the data line 171 and the driving voltage line 172 may extend in the perpendicular direction (or the second direction). The data line 171 may be connected to the connector 171 CM of the first data conductive layer through the lower organic layer opening OP3.

In an embodiment, the data line 171 may extend in the perpendicular direction and may be bent, and the data line 171 at the bent portion may configure a boundary of the photosensor region OPS. The adjacent photosensor regions OPS may configure a first component area EA1.

In an embodiment, the driving voltage line 172 may be connected to the extension FL-SD1 of the first data conductive layer through the lower organic layer opening OP3.

In an embodiment, the anode connecting electrode ACM2 may be electrically connected to the anode connecting electrode ACM1 of the first data conductive layer through the opening OP3.

In an embodiment and referring to FIG. 19, the driving voltage line 172 further includes an extension FL-SD2 and a protruding wire 172-e, and is not formed on a portion where the anode connecting electrode ACM2 is formed.

In an embodiment, the extension FL-SD2 is formed to be wide to planarize the anode disposed on the upper portion.

In an embodiment, the two protruding wires 172-e of the driving voltage line 172 are formed on each side of the two data lines 171 so four wires 171 and 172-e are disposed on the lower portion of the anode to planarize the anode disposed on the upper portion. Referring to FIG. 20, the two data lines 171 formed near each other are bent in the opposite directions to have a portion where a big gap is generated, and the portion corresponds to the photosensor region OPS. One photosensor region OPS is disposed between the two adjacent pixel circuits. The left and right boundaries of the photosensor region OPS are configured with two data lines 171, a lower boundary may be configured by the first scan line 151, and an upper boundary may be configured by the lower second scan line 152a and/or the second scan line 152b. Depending on the embodiments, a portion 1134 of the first semiconductor layer 130 overlapping the data line 171 in a plan view may configure the left and right boundaries of the photosensor region OPS.

In an embodiment, the anode has the planarization characteristic by the structure of the lower portion of the anode.

In an embodiment, the second data conductive layer may include a metal such as aluminum (Al), copper (Cu), molybdenum (Mo), or titanium (Ti), or a metal alloy, and may be configured to be a single layer or a multilayer.

FIG. 20 shows a layer in addition to the second data conductive layer of FIG. 19 so the structure of the pixel circuit on the lower panel layer of FIG. 20 will now be described.

In an embodiment and referring to FIG. 20, a metal layer BML is disposed on a substrate (refer to 110 of FIG. 26).

In an embodiment, the substrate 110 may include a material that has a rigid characteristic and does not bend, such as plastic, or may include a flexible material that is bent such as a polyimide. As shown in FIG. 26, the flexible substrate may have a structure in which a two-layered structure of a barrier layer made of a polyimide and an inorganic insulating material disposed thereon may have a double structure.

In an embodiment, the metal layer BML includes a plurality of extensions BML1 and a connector BML2 for connecting the extensions BML1, where the extension BML1 of the metal layer BML may be formed on a position overlapping the channel 1132 of the driving transistor T1 from among the first semiconductor layer in a plan view. The metal layer BML may also be referred to as a lower shielding layer, may include a metal such as copper (Cu), molybdenum (Mo), aluminum (Al), or titanium (Ti), or a metal alloy thereof, may additionally include amorphous silicon, and may be made of a single layer or a multilayer.

In an embodiment and referring to FIG. 26, a buffer layer 111 for covering the substrate 110 and the metal layer BML may be disposed on the substrate 110 and the metal layer BML. The buffer layer 111 blocks permeation of impure elements into the first semiconductor layer 130, and it may be an inorganic insulating layer including silicon oxide (SiOx), silicon nitride (SiNx), and silicon oxynitride (SiOxNy).

In an embodiment, a first semiconductor layer 130 made of a silicon semiconductor (e.g., a polycrystalline semiconductor) is disposed on the buffer layer 111. The first semiconductor layer 130 includes a channel 1132, a first region 1131, and a second region 1133 of the driving transistor T1. The first semiconductor layer 130 includes channels of a second transistor T2, a fifth transistor T5, and a sixth transistor T6 in addition to the driving transistor T1, and each side of the respective channels has regions with a conductive layer characteristic by a plasma process or doping and functions as the first electrode and the second electrode. The transistor including the first semiconductor layer 130 may be referred to as a polycrystalline semiconductor transistor.

In an embodiment, the channel 1132 of the driving transistor T1 may have a bent U shape in a plan view. The shape of the channel 1132 of the driving transistor T1 is not limited thereto, and may be variable in many ways. For example, the channel 1132 of the driving transistor T1 may be bent in other shapes and may have a bar shape. The first region 1131 and the second region 1133 of the driving transistor T1 may be disposed on respective sides of the channel 1132 of the driving transistor T1. The first region 1131 and the second region 1133 disposed on the first semiconductor layer function as the first electrode and the second electrode of the driving transistor T1.

In an embodiment, a channel, a first region, and a second region of the second transistor T2 are disposed on a portion 1134 extending downward from the first region 1131 of the driving transistor T1 on the first semiconductor layer 130. A channel, a first region, and a second region of the fifth transistor T5 are disposed on a portion 1135 extending upward from the first region 1131 of the driving transistor T1. A channel, a first region, and a second region of the sixth transistor T6 are disposed on a portion 1136 extending upward from the second region 1133 of the driving transistor T1.

In an embodiment and referring to FIG. 26, a first gate insulating layer 141 may be disposed on the first semiconductor layer 130 including the channel 1132, the first region 1131, and the second region 1133 of the driving transistor T1. The first gate insulating layer 141 may be an inorganic insulating layer including silicon oxide (SiOx), silicon nitride (SiNx), and silicon oxynitride (SiOxNy).

In an embodiment, a first gate conductive layer including a gate electrode 1151 of the driving transistor T1 may be disposed on the first gate insulating layer 141. The first gate conductive layer includes gate electrodes of each of the second transistor T2, the fifth transistor T5, and the sixth transistor T6 in addition to the driving transistor T1. The gate electrode 1151 of the driving transistor T1 may overlap the channel 1132 of the driving transistor T1. The channel 1132 of the driving transistor T1 is covered by the gate electrode 1151 of the driving transistor T1.

In an embodiment, the first gate conductive layer may further include a first scan line 151 and a light emitting control line 155. The first scan line 151 and the light emitting control line 155 may substantially extend in a horizontal direction (or a first direction). The first scan line 151 may be connected to a gate electrode of the second transistor T2. The first scan line 151 may be integrally formed with the gate electrode of the second transistor T2.

In an embodiment, the light emitting control line 155 may be connected to the gate electrode of the fifth transistor T5 and the gate electrode of the sixth transistor T6, and the light emitting control line 155 and the gate electrodes of the fifth transistor T5 and the sixth transistor T6 may be integrally formed.

In an embodiment, the first gate conductive layer may include a metal such as copper (Cu), molybdenum (Mo), aluminum (Al), or titanium (Ti), or a metal alloy thereof, and may be configured to be a single layer or a multilayer.

In an embodiment, after forming the first gate conductive layer including the gate electrode 1151 of the driving transistor T1, a plasma process or a doping process may be performed to make an exposed region of the first semiconductor layer a conductor. That is, the first semiconductor layer covered by the first gate conductive layer may not be made conductive, and the portion of the first semiconductor layer not covered by the first gate conductive layer may have a same characteristic as the conductive layer. As a result, the transistor including a conductive portion may be a p-type transistor, and the driving transistor T1, the second transistor T2, the fifth transistor T5, and the sixth transistor T6 may be p-type transistors.

In an embodiment and referring to FIG. 26, a second gate insulating layer 142 may be disposed on the first gate conductive layer including the gate electrode 1151 of the driving transistor T1 and the first gate insulating layer 141. The second gate insulating layer 142 may be an inorganic insulating layer including silicon oxide (SiOx), silicon nitride (SiNx), and silicon oxynitride (SiOxNy).

In an embodiment, a second gate conductive layer including A first storage electrode 1153 of a storage capacitor Cst, a lower shielding layer 3155 of the third transistor T3, and a lower shielding layer 4155 of the fourth transistor T4 may be disposed on the second gate insulating layer 142. The lower shielding layers 3155 and 4155 may be disposed on the lower portions of the channels of the third transistor T3 and the fourth transistor T4 and may shield the channels from light or electromagnetic interference provided to the channels from the lower side.

In an embodiment, the first storage electrode 1153 overlaps the gate electrode 1151 of the driving transistor T1 to configure the storage capacitor Cst. An opening 1152 is formed in the first storage electrode 1153 of the storage capacitor Cst. The opening 1152 of the first storage electrode 1153 of the storage capacitor Cst may overlap the gate electrode 1151 of the driving transistor T1. The first storage electrode 1153 is connected to the adjacent first storage electrode 1153 disposed in the horizontal direction (or the first direction).

In an embodiment, the lower shielding layer 3155 of the third transistor T3 may overlap a channel 3137 of the third transistor T3 and a gate electrode 3151. The lower shielding layer 4155 of the fourth transistor T4 may overlap a channel 4137 of the fourth transistor T4 and a gate electrode 4151.

In an embodiment, the second gate conductive layer may further include a lower second scan line 152a, a lower initialization control line 153a, and a first initialization voltage line 127. The lower second scan line 152a, the lower initialization control line 153a, and the first initialization voltage line 127 may substantially extend in the horizontal direction (or first direction). The lower second scan line 152a may be connected to the lower shielding layer 3155 of the third transistor T3. The lower second scan line 152a may be integrally formed with the lower shielding layer 3155 of the third transistor T3. The lower initialization control line 153a may be connected to the lower shielding layer 4155 of the fourth transistor T4. The lower initialization control line 153a may be integrally formed with the lower shielding layer 4155 of the fourth transistor T4.

In an embodiment, the second gate conductive layer GAT2 may include a metal such as copper (Cu), molybdenum (Mo), aluminum (Al), or titanium (Ti), or a metal alloy thereof, and may be made into a single layer or a multilayer.

In an embodiment and referring to FIG. 26, a first interlayer insulating layer 161 may be disposed on the second gate conductive layer including the first storage electrode 1153 of the storage capacitor Cst, the lower shielding layer 3155 of the third transistor T3, and the lower shielding layer 4155 of the fourth transistor T4. The first interlayer insulating layer 161 may be an inorganic insulating layer including silicon oxide (SiOx), silicon nitride (SiNx), and silicon oxynitride (SiOxNy), and the inorganic insulating material may be made thick depending on an embodiment.

In an embodiment, an oxide semiconductor layer including a channel 3137, a first region 3136 and a second region 3138 of the third transistor T3, a channel 4137, a first region 4136 and a second region 4138 of the fourth transistor T4, and a channel 7137, a first region 7136, and a second region 7138 of the seventh transistor T7 may be disposed on the first interlayer insulating layer 161. The oxide semiconductor layer may further include an upper boost electrode 3138t of a boost capacitor Cboost.

In an embodiment, the channel 3137, the first region 3136, and the second region 3138 of the third transistor T3, and the channel 4137, the first region 4136, and the second region 4138 of the fourth transistor T4 may be connected to each other and may be integrally formed. The channel 7137, the first region 7136, and the second region 7138 of the seventh transistor T7 may be separated from the channel 3137 of the third transistor T3 and the channel 4137 of the fourth transistor T4 so the oxide semiconductor layer may be divided into two portions separated from each other.

In an embodiment, the first region 3136 and the second region 3138 of the third transistor T3 are disposed on the respective sides of the channel 3137 of the third transistor T3, and the first region 4136 and the second region 4138 of the fourth transistor T4 are disposed on the respective sides of the channel 4137 of the fourth transistor T4. The second region 3138 of the third transistor T3 is connected to the second region 4138 of the fourth transistor T4. The channel 3137 of the third transistor T3 overlaps the lower shielding layer 3155, and the channel 4137 of the fourth transistor T4 overlaps the lower shielding layer 4155. The first region 7136 and the second region 7138 of the seventh transistor T7 are disposed on the respective sides of the channel 7137 of the seventh transistor T7. The transistor including an oxide semiconductor layer may be referred to as an oxide semiconductor transistor.

In an embodiment, an upper boost electrode 3138t of the boost capacitor Cboost is disposed between the second region 3138 of the third transistor T3 and the second region 4138 of the fourth transistor T4. The upper boost electrode 3138t of the boost capacitor Cboost overlaps a portion (or a lower boost electrode of the boost capacitor Cboost) of the first scan line 151 to configure the boost capacitor Cboost.

In an embodiment and referring to FIG. 26, a third gate insulating layer 143 may be disposed on the oxide semiconductor layer including the channel 3137, the first region 3136, and the second region 3138 of the third transistor T3, the channel 4137, the first region 4136, and the second region 4138 of the fourth transistor T4, the channel 7137, the first region 7136, and the second region 7138 of the seventh transistor T7, and the upper boost electrode 3138t of the boost capacitor Cboost.

In an embodiment, the third gate insulating layer 143 may be disposed on front surfaces of the oxide semiconductor layer and the first interlayer insulating layer 161. Therefore, the third gate insulating layer 143 may cover the channel 3137, the first region 3136, and the second region 3138 of the third transistor T3, the channel 4137, the first region 4136, and the second region 4138 of the fourth transistor T4, and an upper surface and a lateral surface of the upper boost electrode 3138t of the boost capacitor Cboost. However, the invention is not limited thereto, and the third gate insulating layer 143 may not be disposed on the front surfaces of the oxide semiconductor layer and the first interlayer insulating layer 161. For example, the third gate insulating layer 143 may overlap the channel 3137 of the third transistor T3 and may not overlap the first region 3136 and the second region 3138. In addition, the third gate insulating layer 143 may overlap the channel 4137 of the fourth transistor T4 and may not overlap the first region 4136 and the second region 4138.

In an embodiment, the third gate insulating layer 143 may include an inorganic insulating layer including silicon oxide (SiOx), silicon nitride (SiNx), and silicon oxynitride (SiOxNy).

In an embodiment, a third gate conductive layer including the gate electrode 3151 of the third transistor T3, the gate electrode 4151 of the fourth transistor T4, and the gate electrode 7151 of the seventh transistor T7 may be disposed on the third gate insulating layer 143.

In an embodiment, the gate electrode 3151 of the third transistor T3 may overlap the channel 3137 of the third transistor T3. The gate electrode 3151 of the third transistor T3 may overlap the lower shielding layer 3155 of the third transistor T3.

In an embodiment, the gate electrode 4151 of the fourth transistor T4 may overlap the channel 4137 of the fourth transistor T4. The gate electrode 4151 of the fourth transistor T4 may overlap the lower shielding layer 4155 of the fourth transistor T4.

In an embodiment, the gate electrode 7151 of the seventh transistor T7 may overlap the channel 7137 of the seventh transistor T7.

In an embodiment, the third gate conductive layer may further include an upper second scan line 152b, an upper initialization control line 153b, and a bypass control line 154.

In an embodiment, the upper second scan line 152b, the upper initialization control line 153b, and the bypass control line 154 may substantially extend in the horizontal direction (or the first direction). The upper second scan line 152b configures the second scan line 152 with the lower second scan line 152a. The upper second scan line 152b may be connected to the gate electrode 3151 of the third transistor T3. The upper second scan line 152b may be integrally formed with the gate electrode 3151 of the third transistor T3. The upper initialization control line 153b configures an initialization control line 153 with the lower initialization control line 153a. The upper initialization control line 153b may be connected to a gate electrode 4151 of the fourth transistor T4. The upper initialization control line 153b may be integrally formed with the gate electrode 4151 of the fourth transistor T4.

In an embodiment, the bypass control line 154 may be connected to the gate electrode 7151 of the seventh transistor T7, and the bypass control line 154 may be integrally formed with the gate electrode 7151 of the seventh transistor T7.

In an embodiment, the third gate conductive layer may further include a lower second initialization voltage line 128a. The lower second initialization voltage line 128a may substantially extend in the horizontal direction (first direction), and a second initialization voltage AVinit is applied.

In an embodiment, the third gate conductive layer GAT3 may include a metal such as copper (Cu), molybdenum (Mo), aluminum (Al), or titanium (Ti), or a metal alloy thereof, and may be configured to be a single layer or a multilayer.

In an embodiment, after forming the third gate conductive layer including the gate electrode 3151 of the third transistor T3, the gate electrode 4151 of the fourth transistor T4, and the gate electrode 7151 of the seventh transistor T7, a plasma process or a doping process is performed to form a portion of the oxide semiconductor layer covered by the third gate conductive layer to be a channel and the portion of the oxide semiconductor layer not covered by the third gate conductive layer is conductive. The channel 3137 of the third transistor T3 may be disposed below the gate electrode 3151 so that the channel 3137 overlaps the gate electrode 3151. The first region 3136 and the second region 3138 of the third transistor T3 may not overlap the gate electrode 3151. The channel 4137 of the fourth transistor T4 may be disposed below the gate electrode 4151 to overlap the gate electrode 4151. The first region 4136 and the second region 4138 of the fourth transistor T4 may not overlap the gate electrode 4151. The channel 7137 of the seventh transistor T7 may be disposed below the gate electrode 7151 to overlap the gate electrode 7151. The first region 7136 and the second region 7138 of the seventh transistor T7 may not overlap the gate electrode 7151. The upper boost electrode 3138t may not overlap the third gate conductive layer and thus can have the same/similar characteristics as the conductive characteristics of the conductor. The transistor including an oxide semiconductor layer may have the characteristics of the n-type transistor.

In an embodiment and referring to FIG. 26, the second interlayer insulating layer 162 may be disposed on the third gate conductive layer including the gate electrode 3151 of the third transistor T3, the gate electrode 4151 of the fourth transistor T4, and the gate electrode 7151 of the seventh transistor T7. The second interlayer insulating layer 162 may have a single-or multi-layered structure. The second interlayer insulating layer 162 may be an inorganic insulating layer including silicon oxide (SiOx), silicon nitride (SiNx), and silicon oxynitride (SiOxNy), and may include an organic material depending on embodiments.

In an embodiment, the second interlayer insulating layer 162 may include two types of openings OP1 and OP2. The openings OP1 and OP2 may be formed by using different masks.

In an embodiment, the opening OP1 may be made in at least one of the second interlayer insulating layer 162, the third gate insulating layer 143, the first interlayer insulating layer 161, the second gate insulating layer 142, and the first gate insulating layer 141, and may expose the first semiconductor layer 130, the first gate conductive layer, or the second gate conductive layer.

In an embodiment, the opening OP2 may be made in the second interlayer insulating layer 162 and/or the third gate insulating layer 143 and may expose the oxide semiconductor layer or the third gate conductive layer.

In an embodiment, one of the openings OP1 may overlap at least part of the gate electrode 1151 of the driving transistor T1 and may also be formed in the third gate insulating layer 143, the first interlayer insulating layer 161, and the second gate insulating layer 142. One of the openings OP1 may overlap the opening 1152 of the first storage electrode 1153 and may be disposed inside the opening 1152 of the first storage electrode 1153.

In an embodiment, one of the openings OP2 may overlap at least part of the boost capacitor Cboost and may be further formed in the third gate insulating layer 143.

In an embodiment, another of the openings OP1 may overlap at least part of the second region 1133 of the driving transistor T1 and may be formed in the third gate insulating layer 143, the first interlayer insulating layer 161, the second gate insulating layer 142, and the first gate insulating layer 141.

In an embodiment, another of the openings OP2 may overlap at least part of the first region 3136 of the third transistor T3 and may be formed in the third gate insulating layer 143.

In an embodiment, a first data conductive layer including a first connection electrode 1175 and a second connection electrode 3175 may be disposed on the second interlayer insulating layer 162.

In an embodiment, a first end of the first connection electrode 1175 may overlap the gate electrode 1151 of the driving transistor T1. The first end of the first connection electrode 1175 may be connected to the gate electrode 1151 of the driving transistor T1 through the opening OP1 and the opening 1152 of the first storage electrode 1153. A second end of the first connection electrode 1175 may overlap the boost capacitor Cboost. The second end of the first connection electrode 1175 may be connected to the upper boost electrode 3138t of the boost capacitor Cboost through the opening OP2. Therefore, the gate electrode 1151 of the driving transistor T1 may be connected to the upper boost electrode 3138t of the boost capacitor Cboost by the first connection electrode 1175. The gate electrode 1151 of the driving transistor T1 may be connected to the second region 3138 of the third transistor T3 and the second region 4138 of the fourth transistor T4 by the first connection electrode 1175.

In an embodiment, a first end of the second connection electrode 3175 may overlap the second region 1133 of the driving transistor T1. The first end of the second connection electrode 3175 may be connected to the second region 1133 of the driving transistor T1 through the opening OP1. The second end of the second connection electrode 3175 may overlap the first region 3136 of the third transistor T3. The second end of the second connection electrode 3175 may be connected to the first region 3136 of the third transistor T3 through the opening OP2. Therefore, the second region 1133 of the driving transistor T1 may be connected to the first region 3136 of the third transistor T3 by the second connection electrode 3175, and the first semiconductor layer 130 may be electrically connected to the oxide semiconductor layer.

In an embodiment, the first data conductive layer may further include a second initialization voltage line 128b. The second initialization voltage line 128 includes a wire portion 128b-1 extending in the perpendicular direction (or the second direction) and a first expansion portion 128b-2 protruding to both sides of the horizontal direction (or the first direction) from the wire portion 128b-1, and an end of the first expansion portion 128b-2 may be extended. The extended end of the first expansion portion 128b-2 may be electrically connected to the lower second initialization voltage line 128a disposed on the third gate conductive layer and the second region 7138 of the seventh transistor T7 disposed on the oxide semiconductor layer through the two different openings OP2. As a result, the second initialization voltage AVinit is transmitted in the horizontal direction (or the first direction) through the lower second initialization voltage line 128a disposed on the third gate conductive layer, and the first data conductive layer is transmitted in the perpendicular direction (or the second direction) through the second initialization voltage line 128b. The second initialization voltage AVinit is supplied to the second region 7138 of the seventh transistor T7.

In an embodiment, the first data conductive layer may further include connectors 127 CM and 171 CM, an anode connecting electrode ACM1, and an extension FL-SD1.

In an embodiment, the connector 127 CM is connected to the first initialization voltage line 127 of the second gate conductive layer through the opening OP1 and is connected to the first region 4136 of the second semiconductor layer (or the oxide semiconductor layer) through the opening OP2 to transmit a first initialization voltage Vinit flowing through the first initialization voltage line 127 to the fourth transistor T4 of the oxide semiconductor layer.

In an embodiment, the connector 171 CM is electrically connected to the end of the portion 1134 of the first semiconductor layer 130—that is, the second transistor T2 through the opening OP1.

In an embodiment, the anode connecting electrode ACM1 is electrically connected to the end of the portion 1136 of the first semiconductor layer 130—that is, the sixth transistor T6 through the opening OP1.

In an embodiment, the extension FL-SD1 is formed wide to planarize the anode disposed on the upper portion. The extension FL-SD1 is also connected to the portion 1135 of the first semiconductor layer 130—that is, the fifth transistor T5 through the opening OP1—and is electrically connected to the first storage electrode 1153 through the opening OP1.

In an embodiment, the first data conductive layer SD1 may include a metal such as aluminum (Al), copper (Cu), molybdenum (Mo), or titanium (Ti), or a metal alloy, and may be configured to be a single layer or a multilayer.

In an embodiment and referring to FIG. 26, the first organic layer 181 may be disposed on the first data conductive layer including the first connection electrode 1175 and the second connection electrode 3175. The first organic layer 181 may be an organic insulator including an organic material, and the organic material may include at least one material of a polyimide, a polyamide, an acryl resin, a benzocyclobutene, and a phenol resin.

In an embodiment, a lower organic layer opening OP3 is disposed on the first organic layer 181. A second data conductive layer including the data line 171, the driving voltage line 172, and the anode connecting electrode ACM2 may be disposed on the first organic layer 181. The second organic layer 182 and the third organic layer 183 are disposed on the second data conductive layer, and the anode connecting opening OP4 is formed in the second organic layer 182 and the third organic layer 183. The anode connecting electrode ACM2 is electrically connected to the anode through the anode connecting opening OP4. FIG. 19 shows a top plan view on the second data conductive layer and the openings OP3 and OP4 because it may be difficult to recognize the second data conductive layer in FIG. 20, and FIG. 20 shows a top plan view on the second data conductive layer and the layers therearound.

In an embodiment and referring to FIG. 19 and FIG. 20, the lower organic layer opening OP3 overlaps and exposes the connector 171 CM, the anode connecting electrode ACM1, and the extension FL-SD1 disposed on the first data conductive layer.

In an embodiment, the second data conductive layer may include a data line 171, a driving voltage line 172, and an anode connecting electrode ACM2.

In an embodiment, the data line 171 and the driving voltage line 172 may substantially extend in the perpendicular direction (or the second direction). The data line 171 is connected to the connector 171 CM of the first data conductive layer through the lower organic layer opening OP3, which in turn is connected to the second transistor T2. The data line 171 may extend in the perpendicular direction and is bent, and the data line 171 on the bent portion may configure the boundary of the photosensor region OPS. The adjacent photosensor regions OPS may configure one first component area EA1.

In an embodiment, the driving voltage line 172 passes through the extension FL-SD1 of the first data conductive layer through the lower organic layer opening OP3 and is electrically connected to the fifth transistor T5 and the first storage electrode 1153.

In an embodiment, the anode connecting electrode ACM2 is electrically connected to the anode connecting electrode ACM1 of the first data conductive layer through the opening OP3 and is electrically connected to the sixth transistor T6.

In an embodiment and referring to FIG. 19, the driving voltage line 172 further includes an extension FL-SD2 and a protruding wire 172-e and is not formed on a portion where the anode connecting electrode ACM2 is formed.

In an embodiment, the extension FL-SD2 is formed wide to planarize the anode disposed on the upper portion.

In an embodiment, the two protruding wires 172-e of the driving voltage line 172 are formed on the respective sides of the two data lines 171 so four wires 171 and 172-e are disposed on the lower portion of the anode to planarize the anode disposed on the upper portion. Referring to FIG. 20, the two data lines 171 formed near each other are bent in opposite directions to have a portion where a big gap is generated, and the portion corresponds to the photosensor region OPS. One photosensor region OPS is disposed between the two adjacent pixel circuits. The left and right boundaries of the photosensor region OPS are configured with two data lines 171, a lower boundary may be configured by the first scan line 151, and an upper boundary may be configured by the lower second scan line 152a and/or the second scan line 152b. Depending on the embodiments, a portion 1134 of the first semiconductor layer 130 overlapping the data line 171 in a plan view may configure the left and right boundaries of the photosensor region OPS.

In an embodiment, the anode has the planarization characteristics by the structure (the extension FL-SD1 and the wire portion 128b-1 of the first data conductive layer, and the extension FL-SD2, the data line 171, and the protruding wire 172-e of the second data conductive layer) of the lower portion of the anode and the organic layers 181, 182, and 183.

In an embodiment, the extension FL-SD1 and the extension FL-SD2 are electrically connected to the driving voltage line 172 to transmit a driving voltage ELVDD.

In an embodiment, the second data conductive layer may include a metal such as aluminum (Al), copper (Cu), molybdenum (Mo), or titanium (Ti), or a metal alloy, and may be configured to be a single layer or a multilayer.

In an embodiment and referring to FIG. 26, the second organic layer 182 and the third organic layer 183 are disposed on the second data conductive layer. The second organic layer 182 and the third organic layer 183 may be organic insulators, and may include at least one material of a polyimide, a polyamide, an acryl resin, a benzocyclobutene, and a phenol resin. The third organic layer 183 may be omitted depending on an embodiment.

In an embodiment, the anode connecting opening OP4 is formed in the second organic layer 182 and the third organic layer 183, and thus the anode is electrically connected to the anode connecting electrode ACM2.

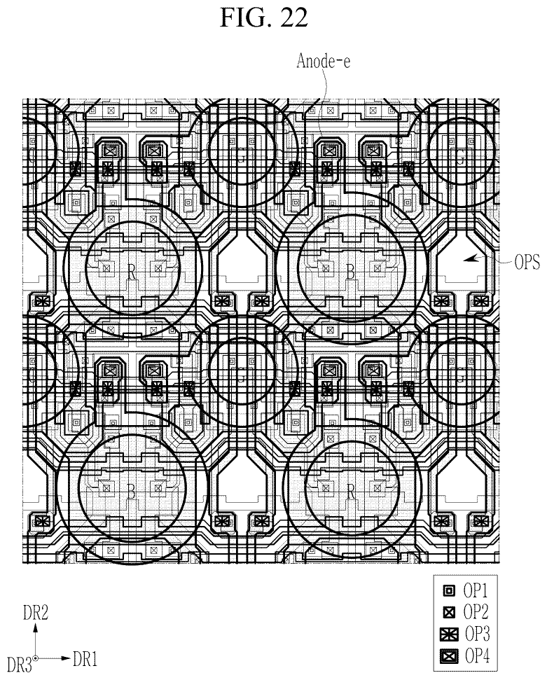

In an embodiment, an anode Anode is formed on the third organic layer 183. The anode Anode may further include an expansion portion Anode-e to receive a current from the pixel circuit through the anode connecting opening OP4. Referring to FIG. 22, two anode connecting openings OP4 may be disposed near each other, and for one of them, the expansion portion Anode-e may extend in the first direction DR1 and may be connected to the anode included in a green-light emitting diode, and for the other, the expansion portion Anode-e may extend in the second direction and may be connected to the anode included in a blue-or red-light emitting diode.

In an embodiment, the pixel defining layer 380 is disposed on the anode Anode, and the opening OP of the pixel defining layer 380 overlaps the anode Anode. The pixel defining layer 380 may be a black pixel defining layer which includes a light blocking material to have a black color and may have a characteristic of absorbing/blocking light without reflecting the light, and the pixel. The expansion portion Anode-e of the anode Anode is not exposed by the opening OP of the pixel defining layer 380 but overlaps the pixel defining layer 380 in a plan view. As a result, the anode connecting opening OP4 overlaps the pixel defining layer 380 in a plan view.

In an embodiment, as the anode connecting opening OP4 does not overlap the opening OP of the pixel defining layer 380 and the second opening OPBM of the light blocking layer 220 in a plan view, it overlaps the pixel defining layer 380 and the light blocking layer 220 in a plan view.

In an embodiment, a portion (a first lower organic layer opening) of the lower organic layer opening OP3 at least partly overlaps the second opening OPBM of the light blocking layer 220, and the remaining lower organic layer opening OP3—that is, the second lower organic layer opening overlaps the light blocking layer 220 in a plan view. The lower organic layer opening OP3 overlaps the pixel defining layer 380 in a plan view.

In an embodiment, a portion exposed by at least the opening OP of the pixel defining layer 380 from the anode Anode may be formed to be planar by the extension FL-SD1 of the first data conductive layer and the extension FL-SD2 of the second data conductive layer disposed on a lower portion of the anode Anode.

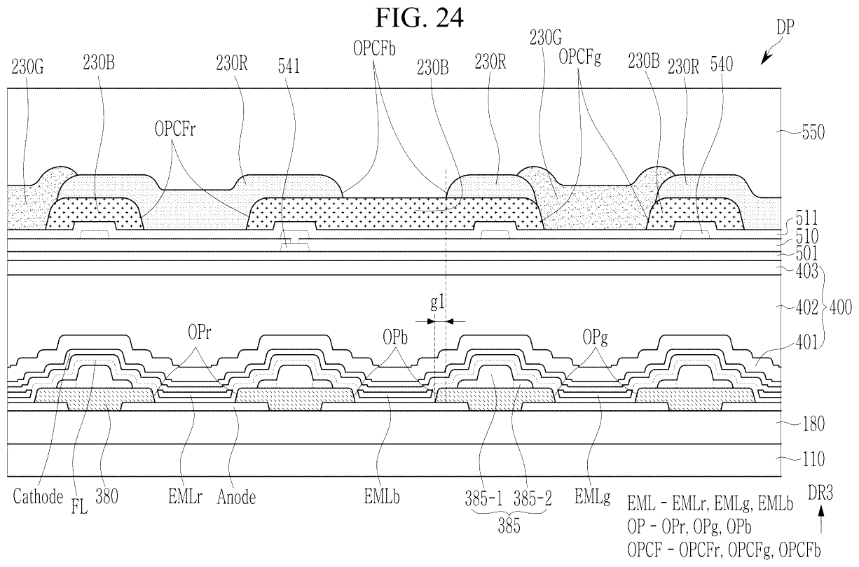

In an embodiment, the overall cross-sectional structure of the light emitting display device may be shown in FIG. 23 or FIG. 24, schematically representing the lower panel layer as described above.

FIG. 23 and FIG. 24 show cross-sectional structures of an embodiment having the light blocking area formed by overlapping at least two color filters instead of the light blocking layer as shown in FIG. 11 to FIG. 14.

A cross-sectional structure of an embodiment of FIG. 23 will now be described.

FIG. 23 shows a cross-sectional view of a display panel, according to an embodiment.

In an embodiment, the light emitting display panel DP may display images by forming light emitting diodes on the substrate 110, may include a plurality of sensing electrodes 540 and 541 to detect touch, and may include the color filters 230R, 230G, and 230B to have the color characteristics of the color filters 230R, 230G, and 230B in the light emitted by the light emitting diode. On the other hand, the light blocking layer is not formed that is black and blocks visible light, and the visible rays are blocked by overlapping at least two color filters instead of the light blocking layer.

In an embodiment, the region for overlapping at least two color filters and blocking the visible rays may be referred to as the light blocking area of the color filter, and in the embodiment of FIG. 23, the blue color filter 230B, the red color filter 230R, and the green color filter 230G are sequentially stacked. The order for stacking the color filters may be varied in many ways depending on the embodiments.

In an embodiment, no polarizer may be formed on the front surface of the light emitting display panel DP, and instead of this, the pixel defining layer 380 may be formed with the black color organic material, the light blocking area of the color filter in which at least two color filters overlap each other may be formed on the upper portion of the pixel defining layer 380 so when external light is incident inside, it may be reflected on the anode Anode and may not be transmitted to the user.

The light emitting display panel DP, according to an embodiment, will now be described in detail.

In an embodiment, the substrate 110 may include a material that does not bend due to rigid characteristics such as glass or may include a flexible material that may bend such as plastic or polyimide.

In an embodiment, thin-film transistors are formed on the substrate 110, which is omitted in FIG. 23, and the organic layer 180 covering the thin-film transistors is shown. One pixel is formed with a pixel circuit in which a light emitting diode, transistors for transmitting light emitting currents to the light emitting diode, and capacitors are formed. FIG. 23 does not show the pixel circuit, and the structure of the pixel circuit may be varied depending on embodiments. FIG. 23 shows the organic layer 180 for covering the pixel circuit.

In an embodiment, the light emitting diode including an anode, an emission layer EML, and a cathode is disposed on the organic layer 180.

In an embodiment, the anode may be made of a single layer including a transparent conductive oxide layer and a metal material or a multilayer including the same. The transparent conductive oxide layer may include indium tin oxide (ITO), a poly-ITO, indium zinc oxide (IZO), indium gallium zinc oxide (IGZO), and indium tin zinc oxide (ITZO), and the metal material may include silver (Ag), molybdenum (Mo), copper (Cu), gold (Au), and aluminum (Al).

In an embodiment, the emission layer EML may be formed of an organic light emitting material, and adjacent emission layers EML may display different colors. Depending on the embodiments, the respective emission layers EML may display light of the same color because of the color filters 230R, 230G, and 230B disposed on the upper portion. Depending on an embodiment, the emission layer EML may have a structure in which emission layers are stacked (also referred to as a tandem structure).

In an embodiment, the pixel defining layer 380 may be disposed on the organic layer 180 and the anode, the pixel defining layer 380 may include an opening OP (also referred to as a first opening), the opening may overlap a portion of the anode, and the emission layer EML may be disposed on the anode exposed by the opening OP. The emission layer EML may be disposed in the opening OP of the pixel defining layer 380, and may be separated from the adjacent emission layer EML by the pixel defining layer 380.

In an embodiment, the pixel defining layer 380 may be made of a negative-type black organic material. The black organic material may include a light blocking material, and the light blocking material may include a resin or a paste including carbon black, carbon nanotube, and black dye, and metal particles—for example, nickel, aluminum, molybdenum, and alloys thereof, and a metal oxide particle (e.g., a chromium nitride). The pixel defining layer 380 may include a light blocking material to have a black color and may have a characteristic of absorbing/blocking light without reflecting the light. Since the negative-type organic material is used, it may have the characteristic of removing a portion covered by the mask.

In an embodiment, a spacer 385 may be formed on the pixel defining layer 380. The spacer 385 includes a first portion 385-1 disposed in a tall and narrow region and a second portion 385-2 disposed in a low and wide region. FIG. 23 shows that the first portion 385-1 and the second portion 385-2 are separated by a dotted line in the spacer 385. Here, the first portion 385-1 may serve to secure rigidity against a pressing pressure by enhancing scratch strength. The second portion 385-2 may serve as a contact aid between the pixel defining layer 380 and the upper function layer FL. The first portion 385-1 and the second portion 385-2 are made of the same material and may be made of a positive-type photosensitive organic material—for example, a photosensitive polyimide (PSPI) may be used. Since it has a positive characteristic, the part not covered by the mask may be removed. The spacer 385 has transparency, so light may be transmitted and/or reflected.

In an embodiment, the pixel defining layer 380 may be formed in a negative type, and the spacer 385 may be formed in a positive type, and they may include the same material depending on the embodiments.

In an embodiment, at least one portion of the upper surface of the pixel defining layer 380 is covered by the spacer 385, and an edge of the second portion 385-2 is spaced apart from an edge of the pixel defining layer 380 so that part of the pixel defining layer 380 is not covered by the spacer 385. The second portion 385-2 may cover the upper surface of the pixel defining layer 380, on which the first portion 385-1 is not disposed, and may increase an adhesion characteristic between the pixel defining layer 380 and the function layer FL. In an embodiment, the spacer 385 may not be visible as it is covered by the light blocking area of the color filter when it is disposed in the region overlapping the light blocking area of the color filter which overlaps at least two color filters and blocks the visible rays, and is seen on the front surface of the display panel DP.

In an embodiment, the function layer FL is disposed on the spacer 385 and the exposed pixel defining layer 380, and the function layer FL may be formed on the front surface of the light emitting display panel DP or in a predetermined region—for example, it may be formed in all regions except the light transmitting region of the second component area EA2. The function layer FL may include an electron injection layer, an electron transport layer, a hole transport layer, and a hole injection layer, and may be disposed above and below the emission layer EML. That is, the hole injection layer, the hole transport layer, the emission layer EML, the electron transport layer, the electron injection layer, and the cathode may be sequentially disposed on the anode, and the hole injection layer and hole transport layer of the function layer FL may be disposed below the emission layer EML, and the electron transport layer and the electron injection layer may be disposed on the emission layer EML.

In an embodiment, the spacer 385 may increase scratch strength on the light emitting display panel DP to reduce a rate of defects caused by the pressing pressure, and depending on the embodiment, it may increase the adherence with the function layer FL disposed on an upper portion of the spacer 385 to prevent moisture and air from entering from the outside. High adhesion has the merit of eliminating the problem of interlayer adhesion falling when the light emitting display panel DP has a flexible characteristic and is folded and unfolded.

In an embodiment, the cathode may be made of a light transmitting electrode or a reflecting electrode. Depending on the embodiment, the cathode may be a transparent or semi-transparent electrode and may be made to be a metal thin layer with a small work function including lithium (Li), calcium (Ca), fluorinated lithium/calcium (LiF/Ca), fluorinated lithium/aluminum (LiF/Al), aluminum (Al), silver (Ag), magnesium (Mg), and their compounds. A transparent conductive oxide (TCO) such as indium tin oxide (ITO), indium zinc oxide (IZO), zinc oxide (ZnO), or indium oxide (In2O3) may be further disposed on the metal thin layer. The cathode may be integrally formed over the front surface of the light emitting display panel DP.

In an embodiment, an encapsulation layer 400 is disposed on the cathode. The encapsulation layer 400 includes at least one inorganic layer and at least one organic layer, and FIG. 23 shows a triple-layer structure including a first inorganic encapsulation layer 401, an organic encapsulation layer 402, and a second inorganic encapsulation layer 403. The encapsulation layer 400 may protect the emission layer EML made of an organic material from moisture or oxygen that may enter from the outside. Depending on the embodiment, the encapsulation layer 400 may include a structure in which an inorganic layer and an organic layer are sequentially further stacked.

In an embodiment, sensing insulating layers 501, 510, and 511 and sensing electrodes 540 and 541 are disposed on the encapsulation layer 400 for touch detection. In an embodiment of FIG. 23, the touch is sensed in a capacitive type using two sensing electrodes 540 and 541, but depending on an embodiment, the touch may be sensed in a self-capping method using one sensing electrode. The sensing electrodes 540 and 541 may be insulated with the second sensing insulating layer 510 interposed therebetween, the lower sensing electrode 541 may be disposed on the first sensing insulating layer 501, the upper sensing electrode 540 may be disposed on the second sensing insulating layer 510, and the upper sensing electrode 540 may be covered by the third sensing insulating layer 511. The sensing electrodes 540 and 541 may be electrically connected through an opening disposed in the second sensing insulating layer 510. Here, the sensing electrodes 540 and 541 may include a metal such as aluminum (Al), copper (Cu), silver (Ag), gold (Au), molybdenum (Mo), or titanium (Ti), or tantalum (Ta), or metal alloys thereof, and may be made of a single layer or a multilayer.

In an embodiment, a light blocking layer 220 and color filters 230R, 230G, and 230B are disposed on the third sensing insulating layer 511. The color filters 230R, 230G, and 230B include a red color filter 230R for transmitting red light, a green color filter 230G for transmitting green light, and a blue color filter 230B for transmitting blue light. Each of the color filters 230R, 230G, and 230B may overlap the anode Anode of the light emitting diode in a plan view. Light emitted by the emission layer EML may pass through the color filter to be changed to the corresponding color and be discharged so the light emitted by the emission layer EML may have the same color. However, the emission layer EML may display different colors of light and may allow the light to pass through the color filter of the same color to thus reinforce the color impression.

Depending on an embodiment, the color filters 230R, 230G, and 230B may be replaced with color conversion layers, or may further include the color conversion layers. The color conversion layers may include quantum dots.

In the embodiment of FIG. 23 a light blocking layer made to have a black color and block the visible rays is not formed, and the light blocking layer is replaced by forming the light blocking area of the color filter formed by overlapping at least two color filters instead of the light blocking layer. The light blocking area of the color filter is a sequential stack of the blue color filter 230B, the red color filter 230R, and the green color filter 230G. The order for stacking the color filters may be modifiable depending on the embodiments.

In an embodiment, the light blocking area of the color filter where at least two color filters overlap each other may overlap the sensing electrodes 540 and 541 in a plan view, and may not overlap the anode Anode in a plan view. This is to prevent the anode Anode and the emission layer EML for displaying images from being covered by the light blocking area of the color filter and the sensing electrodes 540 and 541.

In an embodiment, the light blocking area of the color filter where three color filters overlap are disposed in the region overlapping the pixel defining layer 380 in a plan view, and one side of the light blocking area of the color filter is disposed inward from a corresponding side of the pixel defining layer 380.

In an embodiment and regarding the color filters, one color filter may be disposed in the region exclusive of the light blocking area of the color filter, and the light of the light of the corresponding color filter is transmitted to configure the transmission region of the color filter. Light transmitted through the transmission region of the color filter where one color filter is disposed so the transmission region may also be referred to as a second opening OPCF of the color filter, and the second opening OPCF may be disposed in the light blocking area of the color filter where at least two color filters overlap each other, and may correspond to the region in which one color filter is disposed.

In an embodiment, the second opening OPCF may have a greater area than the opening OP of the pixel defining layer 380, the opening OP of the pixel defining layer 380 in a plan view may be disposed in the second opening OPCF of the color filter, and FIG. 11 shows that a gap between the opening OP of the pixel defining layer 380 and the second opening OPCF of the color filter is shown as g1. As a result, the opening OP of the pixel defining layer 380 may be smaller than the second opening OPCF of the color filter, and a portion of the pixel defining layer 380 may overlap the second opening OPCF of the color filter and may be exposed on the front surface.

According to an embodiment as shown in FIG. 23, the color filters 230R, 230G, and 230B and the second openings OPCFr, OPCFg, and OPCFb may include one of the characteristics of the above-noted thickness, width, structure, and shape.

In an embodiment, a planarization layer 550 for covering color filters 230R, 230G, and 230B is disposed on the color filters 230R, 230G, and 230B. The planarization layer 550 may planarize the upper surface of the light emitting display panel, and may be a transparent organic insulator including at least one material selected from a group consisting of polyimide, polyamide, acrylic resin, benzocyclobutene, and phenolic resin.

Depending on an embodiment, a low-refractive layer and an additional planarization layer may be further disposed on the planarization layer 550 to improve frontal visibility and light emission efficiency of the display panel. Light may be emitted while being refracted to the front surface by the low-refractive layer and an additional planarization layer having high refractive characteristics. In this case, depending on an embodiment, the planarization layer 550 may be omitted and the low-refraction layer and the additional planarization layer may be disposed on the color filter 230.

In an embodiment, the polarizer is not included on the planarization layer 550. That is, the polarizer may prevent external light from entering and reflecting off the anode or the side wall of the opening OP of the pixel defining layer 380 and degrading the display quality as seen by the user. However, the polarizer not only reduces the reflection of external light, but also reduces the light emitted from the emission layer EML, so there is a drawback that more power is required to display a certain brightness. To reduce power consumption, the light emitting display device according to the present embodiment may not include a polarizer.

In an embodiment, the side of the anode Anode is covered with the pixel defining layer 380 to reduce the degree of reflection from the anode Anode, and the light blocking area of the color filter where at least two color filters overlap is formed to reduce the incident degree of light and prevent degradation of display quality caused by reflection. Therefore, it is not necessary to separately form the polarizer on the front surface of the light emitting display panel DP.

In an embodiment, the above discussion has focused on embodiments in which the light blocking area of the color filter with at least two color filters overlap is formed by overlapping three color filters, as shown in FIG. 23. However, depending on an embodiment, the light blocking area of the color filter may be formed by overlapping two color filters, which will now be described with reference to FIG. 24.

FIG. 24 shows a cross-sectional view of a display panel, according to another embodiment.

FIG. 24 corresponds to FIG. 23 and differs from FIG. 23 in that the color filters 230R, 230G, and 230B, and the lower structure of the third sensing insulating layer 511 correspond to those of FIG. 23. An upper structure of the third sensing insulating layer 511, which is different from FIG. 23, will now be mainly described.

In an embodiment and referring to FIG. 24, the light blocking layer for blocking visible rays is not formed, and the blue color filter 230B and the red color filter 230R sequentially overlap to block the visible rays. The order for stacking the color filters may be modifiable depending on the embodiments.

In detail, in an embodiment, the blue color filter 230B and the red color filter 230R overlap the light blocking area of the color filter where the two color filters overlap each other, and the green color filter 230G overlaps a predetermined region of the light blocking area of the color filter. However, the green color filter 230G is not entirely formed in the light blocking area of the color filter so the light blocking area of the color filter is formed with two color filters, unlike the embodiment described with reference to FIG. 23. The light blocking area of the color filter where two color filters overlap is disposed in the region overlapping the pixel defining layer 380 in a plan view, and one side of the light blocking area of the color filter is disposed inward from the corresponding one side of the pixel defining layer 380.

In an embodiment, one color filter may be disposed in the region exclusive of the light blocking area of the color filter, and the light of the corresponding color filter is transmitted to configure the transmission region of the color filter or the second opening OPCF of the color filter. The second opening OPCF may have a greater area than the opening OP of the pixel defining layer 380, and the opening OP of the pixel defining layer 380 in a plan view may be disposed in the second opening OPCF of the color filter.

In an embodiment, the light blocking area of the color filter overlaps the spacer 385 and the sensing electrodes 540 and 541 in a plan view in addition to the pixel defining layer 380.

In an embodiment, the sensing electrodes 540 and 541 are covered with the light blocking area of the color filter in a plan view. As a result, when seen from the front surface of the display panel DP, the spacer 385 and the sensing electrodes 540 and 541 may be covered by the light blocking area of the color filter and may not be visible.

Depending on an embodiment, the color filters 230R, 230G, and 230B may be substituted with the color conversion layers or may further include color conversion layers. The color conversion layer may include quantum dots.

The color filters 230R, 230G, and 230B and the second openings OPCFr, OPCFg, and OPCFb, according to the embodiment given in FIG. 24, may include one of the characteristics of the above-noted thickness, width, structure, and shape.

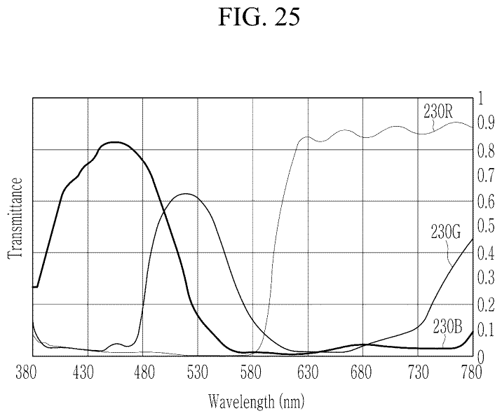

Whether a stack of two color filters may function as the light blocking layer with reference to FIG. 25 will now be examined.

FIG. 25 shows a graph on transmittance with respect to wavelengths of a color filter, according to an embodiment.

FIG. 25 shows an embodiment of a transmittance graph on the wavelengths of the respective color filters 230R, 230G, and 230B, and light with the wavelength marked as high is transmitted. Referring to FIG. 25, it may be found that the portion other than the wavelength band in which light is transmitted in each of the color filters 230R, 230G, and 230B has a transmittance of less than 10%, and there is almost no wavelength band in which light is transmitted when three or two color filters overlap. Therefore, at least two overlapped color filters may function as the light blocking layer so it may be found that when three color filters overlap or two color filters overlap, they may replace the light blocking layer.

A detailed cross-sectional structure of an embodiment including no light blocking layer while overlapping the color filters 230R, 230G, and 230B will now be described with reference to FIG. 26. FIG. 26 shows an embodiment of forming a light blocking area of a color filter by overlapping the blue color filter 230B and the red color filter 230R.

FIG. 26 shows a cross-sectional view of a light emitting display device, according to an embodiment.

FIG. 26 shows a stacking structure of a first component area EA1 in addition to the stacking structure of the display area DA, according to an embodiment.

In an embodiment, the light emitting display device may be divided into a lower panel layer and an upper panel layer, a light emitting diode and pixel circuit for configuring a pixel may be disposed on the lower panel layer, and the light emitting display device may include the encapsulation layer 400 for covering it. Here, the pixel circuit may include the second organic layer 182 and the third organic layer 183 and may represent a lower configuration, and the light emitting diode may be an upper portion of the third organic layer 183 and may be disposed on a lower portion of the encapsulation layer 400. A structure disposed on an upper portion of the encapsulation layer 400 may correspond to the upper panel layer.

In an embodiment and referring to FIG. 26, a metal layer BML is disposed on the substrate 110.

In an embodiment, the substrate 110 may include a material that has a rigid characteristic and is thus not bendable, such as plastic or may include a flexible material that is bendable, such as polyimide. As shown in FIG. 26, the flexible substrate may have a structure in which a two-layered structure of a barrier layer made of polyimide and an inorganic insulating material disposed thereon may have a double structure.

In an embodiment, the metal layer BML may be formed on the position overlapping the channel of the driving transistor T1 from among the first semiconductor layer in a plan view and may be referred to as a lower shielding layer. The metal layer BML may include a metal such as copper (Cu), molybdenum (Mo), aluminum (Al), or titanium (Ti), or metal alloys thereof.

In an embodiment, the buffer layer 111 for covering the substrate 110 and the metal layer BML may be disposed on the substrate 110 and the metal layer BML. The buffer layer 111 blocks permeation of impure elements into the first semiconductor layer ACT(P—Si), and it may be an inorganic insulating layer including silicon oxide (SiOx), silicon nitride (SiNx), and silicon oxynitride (SiOxNy).

In an embodiment, the first semiconductor layer ACT(P—Si) made of a silicon semiconductor (e.g., a polycrystalline semiconductor P—Si) is disposed on the buffer layer 111. The first semiconductor layer includes a channel of a polycrystalline transistor LTPS TFT including the driving transistor T1 and a first region and a second region disposed on respective sides of the channel. Here, the polycrystalline transistor LTPS TFT may include various types of switching transistors and compensation transistors in addition to the driving transistor T1. A region having the characteristic of a conductive layer by a plasma process or a doping process may be disposed on respective sides of the channel of the first semiconductor layer ACT(P—Si) and may function as a first electrode and a second electrode of the transistor.

In an embodiment, the first gate insulating layer 141 may be disposed on the first semiconductor layer ACT(P—Si). The first gate insulating layer 141 may be an inorganic insulating layer including silicon oxide (SiOx), silicon nitride (SiNx), and silicon oxynitride (SiOxNy).

In an embodiment, a first gate conductive layer including a gate electrode GAT1 of the polycrystalline transistor LTPS TFT may be disposed on the first gate insulating layer 141. A first scan line or a light emitting control line in addition to the gate electrode GAT1 of the polycrystalline transistor LTPS TFT may be formed on the first gate conductive layer. The first gate conductive layer may include a metal such as copper (Cu), molybdenum (Mo), aluminum (Al), or titanium (Ti), or a metal alloy, and may be configured to be a single layer or a multilayer.

In an embodiment, the exposed region of the first semiconductor layer may be made into a conductor by forming the first gate conductive layer and performing a plasma process or a doping process. That is, the first semiconductor layer ACT(P—Si) covered by the first gate conductive layer may not be made a conductor, and the portion of the first semiconductor layer ACT(P—Si) not covered by the first gate conductive layer may have the same characteristic as the conductive layer.

In an embodiment, the second gate insulating layer 142 may be disposed on the first gate conductive layer and the first gate insulating layer 141. The second gate insulating layer 142 may be an inorganic insulating layer including silicon oxide (SiOx), silicon nitride (SiNx), and silicon oxynitride (SiOxNy).

In an embodiment, a second gate conductive layer including one electrode GAT2(Cst) of the sustain capacitor Cst and a lower shielding layer GAT2(BML) of the oxide transistor Oxide TFT may be disposed on the second gate insulating layer 142. The lower shielding layer GAT2(BML) of the oxide transistor Oxide TFT may be disposed on the lower portion of the channel of the oxide transistor Oxide TFT and may shield the channel from light or electromagnetic interference (EMI) supplied to the channel from the lower side. The electrode GAT2(Cst) of the sustain capacitor Cst overlaps the gate electrode GAT1 of the driving transistor T1 to form the sustain capacitor Cst. Depending on an embodiment, the second gate conductive layer may further include a scan line, a control line, and a voltage line. The second gate conductive layer may include a metal such as copper (Cu), molybdenum (Mo), aluminum (Al), or titanium (Ti), or a metal alloy thereof, and may be configured to be a single layer or a multilayer.

In an embodiment, the first interlayer insulating layer 161 may be disposed on the second gate conductive layer. The first interlayer insulating layer 161 may include an inorganic insulating layer including silicon oxide (SiOx), silicon nitride (SiNx), and silicon oxynitride (SiOxNy), and depending on an embodiment, it may form a thick inorganic insulating material.

In an embodiment, an oxide semiconductor layer ACT2(IGZO) including a channel, a first region, and a second region of the oxide transistor Oxide TFT may be disposed on the first interlayer insulating layer 161.

In an embodiment, the third gate insulating layer 143 may be disposed on the oxide semiconductor layer ACT2(IGZO). The third gate insulating layer 143 may be disposed on the front surfaces of the oxide semiconductor layer ACT2(IGZO) and the first interlayer insulating layer 161. The third gate insulating layer 143 may include an inorganic insulating layer including silicon oxide (SiOx), silicon nitride (SiNx), and silicon oxynitride (SiOxNy).

In an embodiment, the third gate conductive layer GAT3 including a gate electrode of the oxide transistor Oxide TFT may be disposed on the third gate insulating layer 143. The gate electrode of the oxide transistor Oxide TFT may overlap the channel. The third gate conductive layer GAT3 may further include a scan line or a control line, and may include a connecting electrode connecting the lower shielding layer GAT2(BML) of the oxide transistor Oxide TFT. The third gate conductive layer GAT3 may include a metal such as copper (Cu), molybdenum (Mo), aluminum (Al), or titanium (Ti), or a metal alloy thereof, and may be configured to be a single layer or a multilayer.

In an embodiment, the second interlayer insulating layer 162 may be disposed on the third gate conductive layer GAT3. The second interlayer insulating layer 162 may have a single-layer or multilayer structure. The second interlayer insulating layer 162 may include an inorganic insulating material such as silicon nitride (SiNx), silicon oxide (SiOx), or silicon oxynitride (SiOxNy), and depending on embodiments, it may include an organic material.

In an embodiment, a first data conductive layer SD1 including connecting electrodes connected to the first regions and second regions of the polycrystalline transistor LTPS TFT and the oxide transistor Oxide TFT may be disposed on the second interlayer insulating layer 162. The first data conductive layer SD1 may include a metal such as aluminum (Al), copper (Cu), molybdenum (Mo), or titanium (Ti), or a metal alloy, and may be configured to be a single layer or a multilayer.

In an embodiment, the first organic layer 181 may be disposed on the first data conductive layer SD1. The first organic layer 181 may be an organic insulator including an organic material, and the organic material may include at least one material of polyimide, polyamide, acrylic resin, benzocyclobutene, and phenolic resin.

In an embodiment, the second data conductive layer including an anode connecting electrode ACM2 may be disposed on the first organic layer 181. The second data conductive layer may include a data line and a driving voltage line. The second data conductive layer may include a metal such as aluminum (Al), copper (Cu), molybdenum (Mo), or titanium (Ti), or a metal alloy thereof, and may be configured to be a single layer or a multilayer.

In an embodiment, the second organic layer 182 and the third organic layer 183 are disposed on the second data conductive layer, and the anode connecting opening OP4 is formed in the second organic layer 182 and the third organic layer 183. The anode connecting electrode ACM2 is electrically connected to the anode through the anode connecting opening OP4. The second organic layer 182 and the third organic layer 183 may be organic insulators, and may include at least one material of polyimide, polyamide, acrylic resin, benzocyclobutene, and phenolic resin. The third organic layer 183 may be omitted depending on an embodiment.

In an embodiment, the pixel defining layer 380 having the opening OP for exposing the anode Anode and covering at least a portion of the anode Anode may be disposed on the anode Anode. The pixel defining layer 380 may be a black pixel defining layer made of a black organic material and may prevent external light from being reflected again to the outside, and may be made of a transparent organic material, depending on an embodiment. Therefore, according to an embodiment, the pixel defining layer 380 may include a negative-type black organic material and may include a black pigment.

In an embodiment, the spacer 385 is disposed on the pixel defining layer 380. The spacer 385 may include a first portion 385-1 disposed in a high and narrow region and a second portion 385-2 disposed in a low and wide region. The spacer 385 may be made of a transparent organic insulating material, differing from the pixel defining layer 380. Depending on an embodiment, the spacer 385 may be made of a positive-type transparent organic material.

In an embodiment, the function layer FL and the cathode may be sequentially formed on the anode Anode, the spacer 385, and the pixel defining layer 380, and may be disposed in the entire region in the display area DA and the first component area EA1. The emission layer EML may be disposed between the function layer FL and may be disposed in the opening OP of the pixel defining layer 380. The function layer FL and the emission layer EML may be collectively referred to as an intermediate layer. The function layer FL may include at least one of auxiliary layers such as an electron injection layer, an electron transport layer, a hole transport layer, or a hole injection layer, and the hole injection layer and the hole transport layer may be disposed on the lower portion of the emission layer EML, and the electron transport layer and the electron injection layer may be disposed on the upper portion of the emission layer EML.

In an embodiment, the encapsulation layer 400 is disposed on the cathode. The encapsulation layer 400 may include at least one inorganic layer and at least one organic layer, and depending on an embodiment, it may have a triple-layered structure including a first inorganic encapsulation layer, an organic encapsulation layer, and a second inorganic encapsulation layer. The encapsulation layer 400 may protect the emission layer EML from external moisture or oxygen. Depending on an embodiment, the encapsulation layer 400 may include a structure in which the inorganic layer and the organic layer are sequentially further stacked.

In an embodiment, the sensing insulating layers 501, 510, and 511 and the sensing electrodes 540 and 541 for sensing touches are disposed on the encapsulation layer 400. In the embodiment of FIG. 26, touches may be sensed according to the capacitive type by using the two sensing electrodes 540 and 541.

In detail, in an embodiment, the first sensing insulating layer 501 is formed on the encapsulation layer 400, and the sensing electrodes 540 and 541 are formed thereon. The sensing electrodes 540 and 541 may be insulated with the second sensing insulating layer 510 therebetween, and some may be electrically connected through the opening disposed in the second sensing insulating layer 510. The sensing electrodes 540 and 541 may include a metal such as aluminum (Al), copper (Cu), silver (Ag), gold (Au), molybdenum (Mo), or titanium (Ti), or tantalum (Ta), or a metal alloy thereof, and may be configured to be a single layer or a multilayer. The third sensing insulating layer 511 is formed on the sensing electrode 540.

In an embodiment, the color filters 230R, 230G, and 230B are disposed on the third sensing insulating layer 511.

In the embodiment of FIG. 26, the light blocking layer may not be included, the function of the light blocking layer may be performed by the overlapped color filters 230R and 230B, and the overlapped color filters 230R and 230B may overlap the sensing electrodes 540 and 541 in a plan view. The overlapped color filters 230R and 230B have the second opening OPCF, and the second opening OPCF of the overlapped color filters 230R and 230B overlaps the opening OP of the pixel defining layer 380. The second opening OPCF of the overlapped color filters 230R and 230B may be wider than the opening OP of the pixel defining layer 380. As a result, the anode Anode overlapped (i.e., exposed by the opening OP of the pixel defining layer 380) in the opening OP of the pixel defining layer 380 may not be covered by the overlapped color filters 230R and 230B. This is to prevent the anode Anode and the emission layer EML for displaying images from being covered by the overlapped color filters 230R and 230B and the sensing electrodes 540 and 541. The overlapped color filters 230R and 230B overlap the anode connecting opening OP4 in a plan view.

In an embodiment, one color filter may be disposed in the second opening OPCF of the overlapped color filters 230R and 230B, and the green color filter 230G is disposed therein in FIG. 26. Depending on an embodiment, the color filters 230R, 230G, and 230B may be replaced with the color conversion layer, or may further include the color conversion layer. The color conversion layer may include quantum dots.

In an embodiment, the color filters 230R, 230G, and 230B and the second opening OPCF according to an embodiment given in FIG. 26 may include one of the characteristics of the above-noted thickness, width, structure, and shape.

In an embodiment, the planarization layer 550 for covering color filters 230R, 230G, and 230B are disposed on the color filters 230R, 230G, and 230B. The planarization layer 550 may planarize the upper surface of the light emitting display panel and may be a transparent organic insulator including at least one material of polyimide, polyamide, acrylic resin, benzocyclobutene, and phenolic resin.

Depending on an embodiment, a low-refraction layer and an additional planarization layer may be further disposed on the planarization layer 550 to improve frontal visibility and light emission efficiency of the display panel. Light may be emitted while being refracted to the front surface by the low-refractive layer and an additional planarization layer having high refractive characteristics. In this case, depending on an embodiment, the planarization layer 550 may be omitted and the low-refraction layer and the additional planarization layer may be disposed on the color filter 230.

In an embodiment, no polarizer is included on the planarization layer 550. That is, the polarizer may prevent degradation of display quality while the user recognizes external light as it is input and reflected on the anode Anode. However, in an embodiment, the side of the anode Anode is covered with the pixel defining layer 380 to reduce the reflection degree from the anode Anode, and the overlapped color filters 230R and 230B are formed to reduce the incident degree of light and prevent degradation of display quality. Therefore, there is no need to form the polarizer on the front surface of the display panel DP.

In an embodiment, FIG. 26 shows a cross-sectional structure of the first component area EA1 formed to transmit light through a portion of the display area DA in addition to the stacking structure of the display area DA.

In an embodiment, the first component area EA1 corresponds to the photosensor region OPS, and the photosensor region openings OPt and OPCFt are disposed so that the photosensor region OPS may not overlap the light blocking area of the color filter formed when the pixel defining layer 380 overlaps the at least two color filters in a plan view.

In an embodiment, the photosensor region OPS of the first component area EA1 may not include the layer, such as a metal layer or a semiconductor layer, for blocking light. For reference, the first optical element ES1 (refer to FIG. 2) may be disposed on the rear surface of the first component area EA1, and may sense the front surface of the light emitting display device through the photosensor region OPS disposed in the first component area EA1.

A layered structure of the first component area EA1 will now be described in detail.

In an embodiment, the buffer layer 111 that is an inorganic insulating layer is disposed on the substrate 110, and the first gate insulating layer 141 and the second gate insulating layer 142 that are inorganic insulating layers are sequentially disposed thereon. The first interlayer insulating layer 161, the third gate insulating layer 143, and the second interlayer insulating layer 162 that are inorganic insulating layers may be sequentially stacked on the second gate insulating layer 142.

In an embodiment, the first organic layer 181, the second organic layer 182, and the third organic layer 183 that are organic insulators may be sequentially stacked on the second interlayer insulating layer 162.

In an embodiment, the function layer FL may be disposed on the third organic layer 183, and the cathode may be disposed thereon.

In an embodiment, the encapsulation layer 400 is disposed on the cathode, and the sensing insulating layers 501, 510, and 511 are sequentially disposed thereon. The encapsulation layer 400 may have a triple-layered structure sequentially including an inorganic encapsulation layer, an organic encapsulation layer, and an inorganic encapsulation layer. The sensing insulating layers 501, 510, and 511 may be inorganic insulating layers.

In an embodiment, the planarization layer 550 may be disposed on the sensing insulating layers 501, 510, and 511.

In an embodiment, the metal layer, the first semiconductor layer, the first gate conductive layer, the second gate conductive layer, the oxide semiconductor layer, the third gate conductive layer, the first data conductive layer, the second data conductive layer, and the anode are not disposed in the first component area EA1. The emission layer EML and the sensing electrodes 540 and 541 are not formed.

Furthermore, in an embodiment, the photosensor region openings OPt and OPCFt may be formed in the pixel defining layer 380 and the light blocking area of the color filter, and the pixel defining layer 380 and the color filter may not be formed in the photosensor region OPS of the first component area EA1. As a result, light may be transmitted through the photosensor region OPS.

Depending on an embodiment, the photosensor region openings OPt and OPCFt may not be formed on the pixel defining layer 380 and the light blocking area of the color filter. In this instance, a sensor disposed on the rear surface may be used when the light in a wavelength bandwidth other than visible light is used, the pixel defining layer 380 and the light blocking area of the color filter are provided, and the light of the corresponding wavelength bandwidth is transmitted.

The embodiment in which three organic layers are formed and the anode connecting opening is formed in the second organic layer and the third organic layer has been described. However, in another embodiment, at least two organic layers may be formed, and in this instance, the anode connecting opening may be disposed in the upper organic layer distant from the substrate, and the lower organic layer opening may be disposed in the lower organic layer.

An embodiment in which the light blocking area is formed by using the stacked color filters and not the light blocking layer has been described with reference to FIG. 23 to FIG. 26.

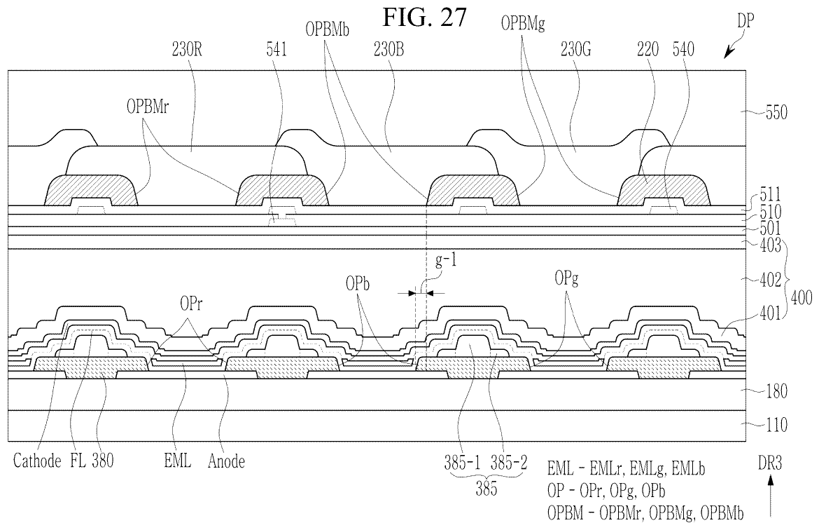

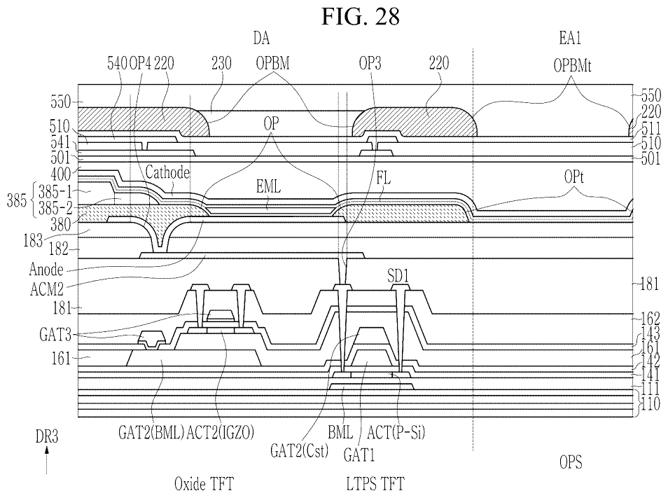

An embodiment of forming a light blocking layer will now be described with reference to FIG. 27 and FIG. 28, and a cross-sectional structure will be first described with reference to FIG. 27.

FIG. 27 shows a cross-sectional view of a display panel, according to another embodiment.

In an embodiment, the light blocking layer 220 is disposed below the color filters 230R, 230G, and 230B, and the second openings OPBMr, OPBMg, and OPBMb are disposed on a portion from which the light blocking layer 220 is removed. One of the color filters 230R, 230G, and 230B is formed in the second openings OPBMr, OPBMg, and OPBMb of the light blocking layer 220.

Portions of FIG. 27 that are different from those of FIG. 23 and FIG. 24 will now be described, according to an embodiment.

In an embodiment, the light blocking layer 220 and the color filters 230R, 230G, and 230B are disposed on the third sensing insulating layer 511.

In an embodiment, the light blocking layer 220 may overlap the sensing electrodes 540 and 541 in a plan view, and may not overlap the anode Anode in a plan view. This is to prevent the anode Anode and the emission layer EML for displaying images from being covered by the light blocking layer 220 and the sensing electrodes 540 and 541.

In an embodiment, the light blocking layer 220 has the second openings OPBMr, OPBMg, and OPBMb, and the second openings OPBMr, OPBMg, and OPBMb of the light blocking layer 220 are wider than the openings OPr, OPg, and OPb of the pixel defining layer 380 by the gap g-1. As a result, when seen on the front surface of the display panel DP, a portion of the pixel defining layer 380 may not be covered by the light blocking layer 220 and may be visible.

In an embodiment, the color filters 230R, 230G, and 230B are disposed on the sensing insulating layers 501, 510, and 511 and the light blocking layer 220. The color filters 230R, 230G, and 230B include a red color filter 230R for transmitting red light, a green color filter 230G for transmitting green light, and a blue color filter 230B for transmitting blue light. The respective color filters 230R, 230G, and 230B may overlap the anode Anode of the light emitting diode in a plan view. Light emitted by the emission layer EML may pass through the color filter to be changed to the corresponding color and be discharged so the light emitted by the emission layer EML may all have the same color. However, the emission layer EML may display different colors of light, and may allow the light to pass through the color filter of the same color to thus reinforce the color impression.

In an embodiment, the light blocking layer 220 may be disposed among the respective color filters 230R, 230G, and 230B. Depending on an embodiment, the color filters 230R, 230G, and 230B may be replaced with color conversion layers, or may further include the color conversion layers. The color conversion layer may include quantum dots.

In an embodiment, the planarization layer 550 for covering the color filters 230R, 230G, and 230B is disposed on the color filters 230R, 230G, and 230B. The planarization layer 550 may planarize the upper surface of the light emitting display panel and may be a transparent organic insulator including at least one material of polyimide, polyamide, acrylic resin, benzocyclobutene, and phenolic resin.

Depending on an embodiment, a low-refraction layer and an additional planarization layer may be further disposed on the planarization layer 550 to improve frontal visibility and light emission efficiency of the display panel. Light may be emitted while being refracted to the front surface by the low-refractive layer and an additional planarization layer having high refractive characteristics. In this case, depending on an embodiment, the planarization layer 550 may be omitted and the low-refractive layer and the additional planarization layer may be disposed on the color filter 230.

In an embodiment, a cover window (refer to WU of FIG. 3) including an antireflection layer may be disposed on the upper portion of the planarization layer 550, and no polarizer is included. That is, the polarizer may prevent degradation of display quality while the user recognizes external light as it is input and reflected on the anode Anode or the side wall of the opening OP of the pixel defining layer 380. However, the polarizer not only reduces the reflection of external light, but also reduces the light emitted from the emission layer EML, so there is a drawback in that more power is consumed to display predetermined brightness. To reduce power consumption, the light emitting display device according to the present embodiment may not include a polarizer. In an embodiment, the side of the anode Anode is covered with the pixel defining layer 380 to reduce the degree of reflection from the anode Anode, and the light blocking layer 220 is formed to reduce the incident degree of light and prevent degradation of display quality caused by reflection. Therefore, it is not necessary to separately form the polarizer on the front surface of the light emitting display panel DP.

A cross-sectional structure of an embodiment of the light emitting display device including a light blocking layer will now be described in detail with reference to FIG. 28.

FIG. 28 shows a cross-sectional view of a light emitting display device, according to another embodiment.

FIG. 28 shows a stacking structure of the first component area EA1 in addition to the stacking structure of the display area DA, according to an embodiment.

The detailed stacking structure of the pixel of the display area DA shown in FIG. 28 up to the anode Anode may correspond to those shown in FIG. 19 to FIG. 22 and/or FIG. 26.

Portions that are different from those of FIG. 26 will be mainly described.

In an embodiment and referring to FIG. 28, the stacking structure of the anode Anode in the pixel of the display area DA is as follows.

In an embodiment, the pixel defining layer 380 having the opening OP exposing the anode Anode and covering at least a portion of the anode Anode may be disposed on the anode Anode. The pixel defining layer 380 is made of a black organic material and prevents external light from being reflected again to the outside. Depending on an embodiment, the pixel defining layer 380 may include a negative-type black organic material and may include a black pigment. Depending on an embodiment, the pixel defining layer made of a material with high transparency may be used instead of the black pixel defining layer 380. Here, a general-purpose polymer such as polystyrene (PS) or an imide-based polymer such as polyimide (PI) may be used as the material with high transparency, which may include a polymer derivative having polymethylmethacrylate (PMMA) or a phenol-based group, and an organic insulating material including an acryl-based polymer, an acryl-based polymer, and a siloxane-based polymer.

In an embodiment, the spacer 385 is disposed on the pixel defining layer 380. The spacer 385 may, differing from the pixel defining layer 380, be made of a transparent organic insulating material. Depending on an embodiment, the spacer 385 may be made of a positive-type transparent organic material.

In an embodiment, the function layer FL and the cathode may be sequentially formed on the anode Anode, the spacer 385, and the pixel defining layer 380, and may be disposed in the entire region in the display area DA and the first component area EA1. The emission layer EML may be disposed between the function layer FL and may be disposed in the opening OP of the pixel defining layer 380. The function layer FL and the emission layer EML may configure an intermediate layer. The function layer FL may include at least one of auxiliary layers including the electron injection layer, the electron transport layer, the hole transport layer, and the hole injection layer, and the hole injection layer and the hole transport layer may be disposed on the lower portion of the emission layer EML, and the electron transport layer and the electron injection layer may be disposed on the upper portion of the emission layer EML.

In an embodiment, the encapsulation layer 400 is disposed on the cathode and may include at least one inorganic layer and at least one organic layer, and depending on an embodiment, it may have a triple-layer structure including a first inorganic encapsulation layer, an organic encapsulation layer, and a second inorganic encapsulation layer. The encapsulation layer 400 may protect the emission layer EML from external moisture or oxygen. Depending on an embodiment, the encapsulation layer 400 may include a structure in which the inorganic layer and the organic layer are sequentially further stacked.

In the embodiment of FIG. 28, the sensing insulating layers 501, 510, and 511 and the sensing electrodes 540 and 541 for sensing touches are disposed on the encapsulation layer 400. Touches may be sensed according to the capacitive type by using the two sensing electrodes 540 and 541.

In detail, in an embodiment, the first sensing insulating layer 501 is formed on the encapsulation layer 400, and the sensing electrodes 540 and 541 are formed thereon. The sensing electrodes 540 and 541 may be insulated with the second sensing insulating layer 510 therebetween, and some may be electrically connected through the opening disposed in the second sensing insulating layer 510. The sensing electrodes 540 and 541 may include a metal such as aluminum (Al), copper (Cu), silver (Ag), gold (Au), molybdenum (Mo), or titanium (Ti), or tantalum (Ta), or a metal alloy, and may be configured to be a single layer or a multilayer. The third sensing insulating layer 511 is formed on the sensing electrode 540.

In an embodiment, the light blocking layer 220 and the color filter 230 are disposed on the sensing electrode 540 and the third sensing insulating layer 511 on the upper portion.

In an embodiment, the light blocking layer 220 may overlap the sensing electrodes 540 and 541 in a plan view and may not overlap the anode Anode in a plan view. This is to prevent the anode Anode for displaying images from being covered by the light blocking layer 220 and the sensing electrodes 540 and 541.

In an embodiment, the color filters 230 may be disposed on the third sensing insulating layer 511 and the light blocking layer 220. The color filters 230 include a red color filter for transmitting red light, a green color filter for transmitting green light, and a blue color filter for transmitting blue light. The color filters 230 may overlap the anode Anode of the light emitting diode in a plan view. Light emitted by the emission layer EML may pass through the color filter to be changed to the corresponding color and discharged.

In an embodiment, the light blocking layer 220 may be disposed between the respective color filters 230. Depending on an embodiment, the color filter 230 may be replaced with the color conversion layer, or may further include the color conversion layer. The color conversion layer may include quantum dots. Depending on an embodiment, a reflection control layer for filling the second opening OPBM of the light blocking layer 220 may be disposed instead of the color filter 230. The reflection control layer may cover the light blocking layer 220.

In an embodiment, the planarization layer 550 for covering the color filters 230 may be disposed on the color filters 230, and the color filter 230 and the light blocking layer 220 may perform an external light antireflection function so no polarizer is additionally attached.

In an embodiment and referring to FIG. 28, the first component area EA1 corresponds to the photosensor region OPS, and the photosensor region openings OPt and OPBMt are disposed so that the photosensor region OPS may not overlap the pixel defining layer 380 and the light blocking layer in a plan view.

In an embodiment, the photosensor region OPS of the first component area EA1 may not include the layer, such as a metal layer or a semiconductor layer, for blocking light. For reference, the first optical element ES1 (refer to FIG. 2) may be disposed on the rear surface of the first component area EA1 and may sense the front surface of the light emitting display device through the photosensor region OPS disposed in the first component area EA1.

In an embodiment, a layered structure of the first component area EA1 will now be described in detail.

In an embodiment, the buffer layer 111 that is an inorganic insulating layer is disposed on the substrate 110, and the first gate insulating layer 141 and the second gate insulating layer 142 that are inorganic insulating layers are sequentially disposed thereon. The first interlayer insulating layer 161, the third gate insulating layer 143, and the second interlayer insulating layer 162 that are inorganic insulating layers may be sequentially stacked on the second gate insulating layer 142.

In an embodiment, the first organic layer 181, the second organic layer 182, and the third organic layer 183 that are organic insulators may be sequentially stacked on the second interlayer insulating layer 162.

In an embodiment, the function layer FL may be disposed on the third organic layer 183, and the cathode may be disposed thereon.

In an embodiment, the encapsulation layer 400 is disposed on the cathode, and the sensing insulating layers 501, 510, and 511 are sequentially disposed thereon. The encapsulation layer 400 may have a triple-layer structure sequentially including an inorganic encapsulation layer, an organic encapsulation layer, and an inorganic encapsulation layer. The sensing insulating layers 501, 510, and 511 may be inorganic insulating layers.

In an embodiment, the planarization layer 550 may be disposed on the sensing insulating layers 501, 510, and 511.

In an embodiment, the metal layer, the first semiconductor layer, the first gate conductive layer, the second gate conductive layer, the oxide semiconductor layer, the third gate conductive layer, the first data conductive layer, the second data conductive layer, and the anode are not disposed in the first component area EA1. The emission layer EML and the sensing electrodes 540 and 541 are not formed.

Furthermore, in an embodiment, the photosensor region openings OPt and OPBMt may be formed in the pixel defining layer 380 and the light blocking layer 220, and the pixel defining layer 380 and the light blocking layer 220 may not be formed in the photosensor region OPS of the first component area EA1. As a result, light may be transmitted through the photosensor region OPS.

Depending on an embodiment, the photosensor region openings OPt and OPBMt may not be formed in the pixel defining layer 380 and the light blocking layer 220. In this instance, a sensor disposed on the rear surface may be used when the light in a wavelength bandwidth other than visible light is used, the pixel defining layer 380 and the light blocking layer 220 are provided, and the light of the corresponding wavelength bandwidth is transmitted.

The embodiment in which three organic layers are formed and the anode connecting opening is formed in the second organic layer and the third organic layer has been described. However, in another embodiment, at least two organic layers may be formed, and in this instance, the anode connecting opening may be disposed in the upper organic layer disposed distant from the substrate, and the lower organic layer opening may be disposed in the lower organic layer.

The embodiment of stacking the color filters 230R, 230G, and 230B of three colors in order of the blue color filter 230B, the red color filter 230R, and the green color filter 230G has been described. Depending on an embodiment, the stacking order may be changed, and the color filter formed last may may be the color filter of another color and not the green color filter 230G. Further, color filters with other three colors in addition to the red, green, and blue colors may be used.

While the invention has been described in connection with what is presently considered to be practical embodiments, it is to be understood that the invention is not limited to the disclosed embodiments, but it is intended to cover various modifications and equivalent arrangements included within the spirit and scope of the invention. Moreover, although embodiments have been described in detail above, the scope of the invention is not limited thereto, and various modifications and improvements made by those skilled in the art using the basic concepts of the invention. Therefore, the scope of the invention is not limited to the contents described in the detailed description of the specification. Moreover, the embodiments or parts of the embodiments may be combined in whole or in part without departing from the scope of the invention.

What is claimed is:

1. A light emitting display device comprising:
a display panel including a normal display area and a component area surrounded by the normal display area and including photosensor regions; and
an optical element disposed on a rear surface of the component area,
wherein the normal display area and the component area of the display panel respectively include
a substrate,
anodes disposed on the substrate,
a pixel defining layer having first openings of the pixel defining layer overlapping each of the anodes,
light emitting layers disposed in the first openings of the pixel defining layer,
a cathode formed on the light emitting layers and the pixel defining layer,
an encapsulation layer disposed on the cathode, and
a light blocking layer disposed on the encapsulation layer and including second openings of the light blocking layer corresponding to the first openings of the pixel defining layer, wherein
an area of the second openings of the light blocking layer in the normal display area corresponding to a first color is formed to be narrower than an area of the second openings of the light blocking layer of the component area.

2. The light emitting display device of claim 1, wherein
the second openings of the light blocking layer of the component area have a narrower width than second openings of the light blocking layer in the normal display area by greater than about 0 μm and equal to or less than about 2 μm.

3. The light emitting display device of claim 1, further comprising
color filters disposed on the light blocking layer,
wherein the color filter of the color formed last from among the color filters has a height difference range equal to or greater than about −0.3 μm and equal to or less than about 0.2 μm in the component area, compared to the normal display area.

4. The light emitting display device of claim 3, wherein
the pixel defining layer further includes a photosensor region first opening corresponding to the photosensor region,
the light blocking layer further includes a photosensor region second opening corresponding to the photosensor region and the photosensor region first opening,
the color filter of one color is disposed in the photosensor region second opening,
the photosensor region first opening is disposed in the pixel defining layer of the normal display area, and
the photosensor region first opening of the normal display area overlaps the light blocking layer.

5. The light emitting display device of claim 3, wherein
an area of the second openings of the light blocking layer of the component area corresponding to a color that is different from the first color is formed to be narrower than an area of the second openings of the light blocking layer of the component area corresponding to the different color of the normal display area,
the second openings of the light blocking layer of the component area corresponding to any color is formed to have a narrower area than the second openings of the light blocking layer of the component area of the corresponding color of the normal display area, and
a ratio of the narrower area of the second openings of the light blocking layer of the component area corresponding to the first color is equal to a ratio of the narrower area of the second openings of the light blocking layer of the component area corresponding to the different color or is different by an amount equal to or less than about 5%.

6. A light emitting display device comprising:
a display panel including a normal display area and a component area surrounded by the normal display area and including photosensor regions; and
an optical element disposed on a rear surface of the component area,
wherein the normal display area and the component area of the display panel respectively include
a substrate,
anodes disposed on the substrate,
a pixel defining layer having first openings overlapping the anodes,
light emitting layers disposed in the first openings of the pixel defining layer,
a cathode formed on the light emitting layers and the pixel defining layer,
an encapsulation layer disposed on the cathode; and
color filters corresponding to different colors disposed on the encapsulation layer,
wherein at least two of the color filters overlap each other in a light blocking area of the color filters, and wherein the color filters include second openings in which one of the color filters is disposed, and
an area of a second opening of the normal display area corresponding to a first color is formed to be narrower than an area of a second opening of the component area.

7. The light emitting display device of claim 6, wherein
the second opening of the component area has a narrower width than the second opening of the normal display area by greater than about 0 μm and equal to or less than about 2 μm.

8. The light emitting display device of claim 6, wherein
the color filter of a color formed last from among the color filters has a height difference greater than or equal to about −0.3 μm and less than or equal to about 0.2 μm in the component area, compared to the normal display area.

9. The light emitting display device of claim 8, wherein
the pixel defining layer further includes a photosensor region first opening of the pixel defining layer corresponding to the photosensor region,
the light blocking area of the color filters further include a photosensor region second opening of the light blocking area corresponding to the photosensor region and the photosensor region first opening of the pixel defining area,
a color filter of one color is disposed in the photosensor region second opening of the light blocking area,
the photosensor region first opening of the light blocking area is disposed in the pixel defining layer of the normal display area, and
the photosensor region first opening of the light blocking area of the normal display area overlaps the light blocking area of the color filter.

10. The light emitting display device of claim 8, wherein
an area of the second opening of the component area corresponding to a color that is different from the first color is formed to be narrower than an area of the second opening normal display area corresponding to the different color of the normal display area,
the second opening of the component area disposed in the component area corresponding to any color is formed to be narrower than an area of the second opening of normal display area of the corresponding color of the normal display area, and
a ratio of the narrower area of the second opening of the component area corresponding to the first color is equal to a ratio of the narrower area of the second opening of the component area corresponding to the different color or is different by an amount that is equal to or less than about 5%.

11. An electronic device comprising:
a light emitting display device, wherein the light emitting display device includes,
a display panel which includes a normal display area and a component area surrounded by the normal display area and including photosensor regions; and
an optical element disposed on a rear surface of the component area,
wherein the normal display area and the component area of the display panel respectively includes
a substrate,
anodes disposed on the substrate,
a pixel defining layer having first openings of the pixel defining layer overlapping each of the anodes,
light emitting layers disposed in the first openings of the pixel defining layer,
a cathode formed on the light emitting layers and the pixel defining layer,
an encapsulation layer disposed on the cathode, and
a light blocking layer disposed on the encapsulation layer and including second openings of the light blocking layer corresponding to the first openings of the pixel defining layer, wherein
an area of the second openings of the light blocking layer in the normal display area corresponding to a first color is formed to be narrower than an area of the second openings of the light blocking layer of the component area.

12. The electronic device of claim 11, wherein
the second openings of the light blocking layer of the component area have a narrower width than second openings of the light blocking layer in the normal display area by greater than about 0 μm and equal to or less than about 2 μm.

13. The electronic device of claim 11, wherein the light emitting display device further includes,
color filters disposed on the light blocking layer,
wherein the color filter of the color formed last from among the color filters has a height difference range equal to or greater than about −0.3 μm and equal to or less than about 0.2 μm in the component area, compared to the normal display area.

14. The electronic device of claim 13, wherein
the pixel defining layer further includes a photosensor region first opening corresponding to the photosensor region,
the light blocking layer further includes a photosensor region second opening corresponding to the photosensor region and the photosensor region first opening,
the color filter of one color is disposed in the photosensor region second opening,
the photosensor region first opening is disposed in the pixel defining layer of the normal display area, and
the photosensor region first opening of the normal display area overlaps the light blocking layer.

15. The electronic device of claim 13, wherein
an area of the second openings of the light blocking layer of the component area corresponding to a color that is different from the first color is formed to be narrower than an area of the second openings of the light blocking layer of the component area corresponding to the different color of the normal display area,
the second openings of the light blocking layer of the component area corresponding to any color is formed to have a narrower area than the second openings of the light blocking layer of the component area of the corresponding color of the normal display area, and
a ratio of the narrower area of the second openings of the light blocking layer of the component area corresponding to the first color is equal to a ratio of the narrower area of the second openings of the light blocking layer of the component area corresponding to the different color or is different by an amount equal to or less than about 5%.

16. An electronic device comprising:
a light emitting display device, wherein the light emitting display device includes,
a display panel including a normal display area and a component area surrounded by the normal display area and including photosensor regions; and
an optical element disposed on a rear surface of the component area,
wherein the normal display area and the component area of the display panel respectively include
a substrate,
anodes disposed on the substrate,
a pixel defining layer having first openings overlapping the anodes,
light emitting layers disposed in the first openings of the pixel defining layer,
a cathode formed on the light emitting layers and the pixel defining layer,
an encapsulation layer disposed on the cathode; and
color filters corresponding to different colors disposed on the encapsulation layer,
wherein at least two of the color filters overlap each other in a light blocking area of the color filters, and wherein the color filters include second openings in which one of the color filters is disposed, and
an area of a second opening of the normal display area corresponding to a first color is formed to be narrower than an area of a second opening of the component area.

17. The electronic device of claim 16, wherein
the second opening of the component area has a narrower width than the second opening of the normal display area by greater than about 0 μm and equal to or less than about 2 μm.

18. The electronic device of claim 16, wherein
the color filter of a color formed last from among the color filters has a height difference greater than or equal to about −0.3 μm and less than or equal to about 0.2 μm in the component area, compared to the normal display area.

19. The electronic device of claim 18, wherein
the pixel defining layer further includes a photosensor region first opening of the pixel defining layer corresponding to the photosensor region,
the light blocking area of the color filters further include a photosensor region second opening of the light blocking area corresponding to the photosensor region and the photosensor region first opening of the pixel defining area,
a color filter of one color is disposed in the photosensor region second opening of the light blocking area,
the photosensor region first opening of the light blocking area is disposed in the pixel defining layer of the normal display area, and
the photosensor region first opening of the light blocking area of the normal display area overlaps the light blocking area of the color filter.

20. The electronic device of claim 18, wherein
an area of the second opening of the component area corresponding to a color that is different from the first color is formed to be narrower than an area of the second opening normal display area corresponding to the different color of the normal display area,
the second opening of the component area disposed in the component area corresponding to any color is formed to be narrower than an area of the second opening of normal display area of the corresponding color of the normal display area, and
a ratio of the narrower area of the second opening of the component area corresponding to the first color is equal to a ratio of the narrower area of the second opening of the component area corresponding to the different color or is different by an amount that is equal to or less than about 5%.
